(19) United States
(12) Patent Application Publication
(10) Pub. No.: US 2024/0423004 A1
(43) Pub. Date: Dec. 19, 2024

(54) IMAGE SENSOR, IMAGING DEVICE, AND METHOD FOR MANUFACTURING IMAGE SENSOR

(71) Applicant: Panasonic Intellectual Property Management Co., Ltd., Osaka (JP)

(72) Inventors: TAKANORI DOI, Kyoto (JP); JUNJI HIRASE, Osaka (JP); RYOTA SAKAIDA, Toyama (JP); SHUNSUKE ISONO, Osaka (JP); YUUKO TOMEKAWA, Osaka (JP)

(21) Appl. No.: 18/822,525

(22) Filed: Sep. 3, 2024

Related U.S. Application Data
(63) Continuation of application No. PCT/JP2023/004831, filed on Feb. 13, 2023.

(30) Foreign Application Priority Data
Mar. 17, 2022 (JP) 2022-042508

(51) Int. Cl. H10K 39/32

(52) U.S. Cl. CPC H10K 39/32

(57) ABSTRACT

An image sensor includes a photoelectric conversion film, an upper electrode, and a connector. The upper electrode is located on or above the photoelectric conversion film. The connector is electrically connected to the upper electrode. On a first section parallel to a direction perpendicular to the photoelectric conversion film, the connector is in contact with the side surface of the photoelectric conversion film. On the first section, the upper electrode extends to a position outward of the outer edge of the upper surface of the photoelectric conversion film.

### BACKGROUND

### 1. Technical Field

The present disclosure relates to an image sensor, an imaging device, and a method for manufacturing the image sensor.

### 2. Description of the Related Art

Image sensors using a complementary metal-oxide-semiconductor (CMOS) or the like are being proposed. Japanese Patent No. 5780402 and International Publication No. WO2019/239851 describe examples of an image sensor.

### SUMMARY

In one general aspect, the techniques disclosed here feature an image sensor including: a photoelectric conversion film; an upper electrode located on or above the photoelectric conversion film; and a connector electrically connected to the upper electrode, in which on a first section parallel to a direction perpendicular to the photoelectric conversion film, the connector is in contact with a side surface of the photoelectric conversion film, and the upper electrode extends to a position outward of an outer edge of an upper surface of the photoelectric conversion film.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a circuit diagram showing the circuit configuration of an imaging device according to Embodiment 1;

FIG. 2 is a sectional view showing the device structure of a pixel according to Embodiment 1;

FIG. 3A is a sectional view of an image sensor according to Embodiment 1;

FIG. 3B is a top view of the image sensor according to Embodiment 1;

FIG. 4A is a partial sectional view of the image sensor according to Embodiment 1;

FIG. 4B is a partial sectional view of the image sensor according to Embodiment 1;

FIG. 4C is a partial sectional view of the image sensor according to Embodiment 1;

FIG. 4D is a partial sectional view of the image sensor according to Embodiment 1;

FIG. 4E is a partial sectional view of the image sensor according to Embodiment 1;

FIG. 4F is a partial sectional view of the image sensor according to Embodiment 1;

FIG. 4G is a partial sectional view of the image sensor according to Embodiment 1;

FIG. 5A is a sectional view showing the process of manufacturing the image sensor according to Embodiment 1;

FIG. 5B is a sectional view showing the process of manufacturing the image sensor according to Embodiment 1;

FIG. 5C is a sectional view showing the process of manufacturing the image sensor according to Embodiment 1;

FIG. 5D is a sectional view showing the process of manufacturing the image sensor according to Embodiment 1;

FIG. 5E is a sectional view showing the process of manufacturing the image sensor according to Embodiment 1;

FIG. 5F is a sectional view showing the process of manufacturing the image sensor according to Embodiment 1;

FIG. 5G is a sectional view showing the process of manufacturing the image sensor according to Embodiment 1;

FIG. 5H is a sectional view showing the process of manufacturing the image sensor according to Embodiment 1;

FIG. 6A is a diagram illustrating dry etching in Embodiment 1;

FIG. 6B is a diagram illustrating dry etching in Embodiment 1;

FIG. 6C is a diagram illustrating dry etching in Embodiment 1;

FIG. 6D is a diagram illustrating dry etching in Embodiment 1;

FIG. 7A is a partial sectional view of an image sensor according to Embodiment 2;

FIG. 7B is a partial sectional view of the image sensor according to Embodiment 2;

FIG. 7C is a partial sectional view of the image sensor according to Embodiment 2;

FIG. 7D is a partial sectional view of the image sensor according to Embodiment 2;

FIG. 7E is a partial sectional view of the image sensor according to Embodiment 2;

FIG. 8A is a diagram illustrating dry etching in Embodiment 2;

FIG. 8B is a diagram illustrating dry etching in Embodiment 2;

FIG. 9A is a partial sectional view of an image sensor according to Embodiment 3;

FIG. 9B is a partial sectional view of the image sensor according to Embodiment 3;

FIG. 9C is a partial sectional view of the image sensor according to Embodiment 3;

FIG. 9D is a partial sectional view of the image sensor according to Embodiment 3;

FIG. 9E is a partial sectional view of the image sensor according to Embodiment 3;

FIG. 10A is a diagram illustrating dry etching in Embodiment 3;

FIG. 10B is a diagram illustrating dry etching in Embodiment 3;

FIG. 11A is a partial sectional view of an image sensor according to Embodiment 4;

FIG. 11B is a partial sectional view of the image sensor according to Embodiment 4;

FIG. 12A is a diagram illustrating dry etching in Embodiment 4;

FIG. 12B is a diagram illustrating dry etching in Embodiment 4;

FIG. 13 is a sectional view showing an image sensor according to another embodiment;

FIG. 14 is a top view showing an image sensor according to another embodiment;

FIG. 15 is a top view showing an image sensor according to another embodiment;

FIG. 16 is a top view showing an image sensor according to another embodiment; and

FIG. 17 is a sectional view showing an image sensor according to another embodiment.

### DETAILED DESCRIPTIONS

### Underlying Knowledge Forming the Basis of the Present Disclosure

In manufacturing of an image sensor, a photoelectric conversion film may be processed by dry etching. In the dry etching of the photoelectric conversion film, plasma or the like may damage the side surface of the photoelectric conversion film. This damage may cause current leakage in the image sensor. Thus, the present disclosure provides a technique suitable for reducing current leakage.

### SUMMARY OF ASPECT OF THE PRESENT DISCLOSURE

An image sensor according to a first aspect of the present disclosure includes:
a photoelectric conversion film;
an upper electrode located on or above the photoelectric conversion film; and
a connector electrically connected to the upper electrode. On a first section parallel to a direction perpendicular to the photoelectric conversion film,
the connector is in contact with a side surface of the photoelectric conversion film, and
the upper electrode extends to a position outward of an outer edge of an upper surface of the photoelectric conversion film.

The first aspect is suitable for reducing current leakage.

In a second aspect of the present disclosure, for example, in the image sensor according to the first aspect,
the upper surface of the photoelectric conversion film may include a contact surface between the photoelectric conversion film and the upper electrode, and
on the first section, at a same position as the contact surface in the direction perpendicular to the photoelectric conversion film, a side surface of the upper electrode may be located outward of the side surface of the photoelectric conversion film.

The configuration of the image sensor of the second aspect is an example configuration of the image sensor.

In a third aspect of the present disclosure, for example, in the image sensor according to the first or second aspect,
on the first section, a side surface of the upper electrode may include a first tapered portion spreading outward from an upper surface of the upper electrode toward a lower surface of the upper electrode.

The configuration of the upper electrode of the third aspect is an example configuration of the upper electrode.

In a fourth aspect of the present disclosure, for example, in the image sensor according to any one of the first to third aspects,
on the first section, an upper edge of the side surface of the photoelectric conversion film may be located more inward in the photoelectric conversion film than a lower edge of the side surface of the photoelectric conversion film.

The fourth aspect is suitable for reducing current leakage.

In a fifth aspect of the present disclosure, for example, the image sensor according to any one of the first to fourth aspects may further include a first crack including a first portion and a second portion,
on the first section,
   the first portion may be located inward and downward of an outer edge of the upper electrode,
   the second portion may be located outward and upward of the outer edge of the upper electrode, and
   the second portion may be located inside the connector.

The first crack of the fifth aspect may mitigate stress in the connector.

In a sixth aspect of the present disclosure, for example, in the image sensor according to any one of the first to fifth aspects,
the photoelectric conversion film may include a photoelectric conversion layer and an upper layer,
the upper layer may be located on or above the photoelectric conversion layer, and
on the first section, a side surface of the upper layer may be located inward of a straight line including an upper edge of a side surface of the photoelectric conversion layer and a lower edge of the side surface of the photoelectric conversion layer.

The sixth aspect is suitable for reducing current leakage and reducing concentration of an electric field.

In a seventh aspect of the present disclosure, for example, in the image sensor according to any one of the first to sixth aspects,
the photoelectric conversion film may include a photoelectric conversion layer and a lower layer,
the lower layer may be located on or below the photoelectric conversion layer, and
on the first section, a side surface of the lower layer may be located inward of a straight line including an upper edge of a side surface of the photoelectric conversion layer and a lower edge of the side surface of the photoelectric conversion layer.

The seventh aspect is suitable for reducing concentration of an electric field.

In an eighth aspect of the present disclosure, for example, in the image sensor according to the seventh aspect,
a lower edge of the side surface of the lower layer may be located inward of an upper edge of the side surface of the lower layer.

The eighth aspect is suitable for reducing concentration of an electric field.

In a ninth aspect of the present disclosure, for example, the image sensor according to the eighth aspect may further include a second crack including a third portion and a fourth portion,
on the first section,
   the third portion may be located inward and downward of the upper edge of the side surface of the lower layer,
   the fourth portion may be located outward and upward of the upper edge of the side surface of the lower layer, and
   the fourth portion may be located inside the connector.

The second crack of the ninth aspect may mitigate stress in the connector.

In a tenth aspect of the present disclosure, for example, in the image sensor according to any one of the first to ninth aspects,
on the first section, the side surface of the photoelectric conversion film may include a second tapered portion spreading outward from the upper surface of the photoelectric conversion film toward a lower surface of the photoelectric conversion film.

The configuration of the photoelectric conversion film of the tenth aspect is an example configuration of the photoelectric conversion film.

In an 11th aspect of the present disclosure, for example, the image sensor according to any one of the first to tenth aspects may further include an insulating film, and
on the first section,
   the connector, the insulating film, and the upper electrode may be disposed in this order from an upper side to a lower side of the image sensor, and
   an upper surface of the upper electrode may be spaced away from the connector.

The positional relationship between the elements in the 11th aspect is an example positional relationship.

In a 12th aspect of the present disclosure, for example, the image sensor according to any one of the first to 11th aspects may further include an insulating film, and
on the first section, a side surface of the insulating film may be continuous with a side surface of the upper electrode.

The positional relationship between the elements in the 12th aspect is an example positional relationship.

In a 13th aspect of the present disclosure, for example, in the image sensor according to any one of the first to 12th aspects,
on a second section of the image sensor parallel to the direction perpendicular to the photoelectric conversion film and orthogonal to the first section, the upper electrode may extend to a position outward of the outer edge of the upper surface of the photoelectric conversion film.

The 13th aspect is suitable for reducing current leakage.

In a 14th aspect of the present disclosure, for example, in the image sensor according to any one of the first to 13th aspects,
a material of the upper electrode may have a light transmittance higher than a light transmittance of a material of the connector.

In a 15th aspect of the present disclosure, for example, in the image sensor according to any one of the first to 14th aspects,
the connector may have a light blocking property.

An imaging device according to a 16th aspect of the present disclosure includes:
the image sensor according to any one of the first to 15th aspects; and
a peripheral circuit that controls the image sensor.

The 16th aspect is suitable for reducing current leakage.

A method for manufacturing an image sensor according to a 17th aspect of the present disclosure includes:
obtaining a structure including a photoelectric conversion film and an upper electrode located on or above the photoelectric conversion film;
by using an etching gas that etches the photoelectric conversion film at an etching rate higher than an etching rate for the upper electrode, performing dry etching to etch a side surface of the photoelectric conversion film while forming a space that is located inward and downward of an outer edge of the upper electrode; and
after the dry etching, disposing a connector that is electrically connected to the upper electrode and that is in contact with the side surface of the photoelectric conversion film. The side surface of the photoelectric conversion film is exposed in the space in the dry etching.

The 17th aspect is suitable for reducing current leakage.

In an 18th aspect of the present disclosure, for example, in the method for manufacturing according to the 17th aspect,
the photoelectric conversion film may include a photoelectric conversion layer and an upper layer,
the upper layer may be located on or above the photoelectric conversion layer, and
in the dry etching, an etching rate for the upper layer may be higher than an etching rate for the photoelectric conversion layer.

The 18th aspect is suitable for reducing current leakage and reducing concentration of an electric field.

In an 19th aspect of the present disclosure, for example, in the method for manufacturing according to the 17th or 18th aspect,
the photoelectric conversion film may include a photoelectric conversion layer and a lower layer,
the lower layer may be located on or below the photoelectric conversion layer, and
in the dry etching, an etching rate for the lower layer may be higher than an etching rate for the photoelectric conversion layer.

The 19th aspect is suitable for reducing concentration of an electric field.

In an 20th aspect of the present disclosure, for example, in the method for manufacturing according to any one of the 17th to 19th aspects,
in the dry etching, a flow of the etching gas may be formed, from a location upward of the upper electrode to a location downward of the upper electrode.

The 20th aspect is suitable for reducing current leakage.

Embodiments of the present disclosure are described below. The embodiments shown below are preferred examples used to illustrate the present disclosure and are not intended to limit the present disclosure. Some elements may be omitted in the drawings. In the drawings, dimensions, tapering angles, and the like may be depicted in an exaggerated manner.

Terms used herein such as “perpendicular,” “up,” “down,” “left,” “right,” and “lateral” are used only to specify the positions of elements relative to one another and are therefore not intended to limit the posture of an image sensor in use.

A “plan view” herein refers to a view as seen in a direction of the thickness of a photoelectric conversion film.

An expression such as “different in the composition of a material” herein includes not only a case where the kinds of elements contained in a material are different, but also a case where the component ratios of elements contained in a material are different.

A “taper” herein may be straight or curved. “Including a taper” refers to having a taper at at least part thereof.

What is meant herein by an element A and an element B in contact with each other is that at least part of the element A and at least part of the element B are in contact with each other. For example, a connector being in contact with a side surface of a photoelectric conversion film means that at least part of the connector is in contact with at least part of the side surface of the photoelectric conversion film.

### Embodiment 1

### Overview of an Imaging Device

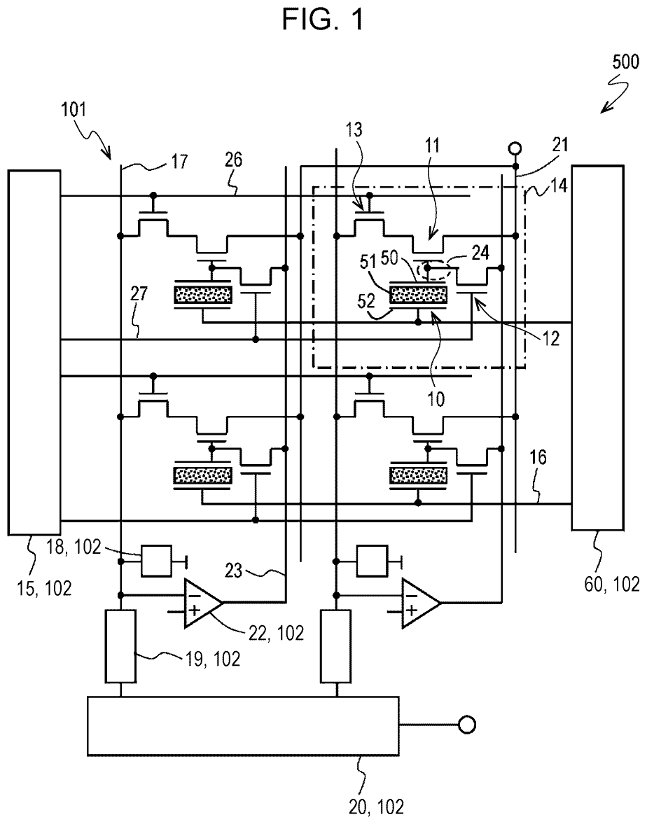

FIG. 1 is a circuit diagram showing the circuit configuration of an imaging device 500 according to Embodiment 1. The imaging device 500 includes an image sensor 101 and peripheral circuits 102. The image sensor 101 includes a plurality of pixels 14.

The plurality of pixels 14 are two-dimensionally arranged on a semiconductor substrate. The plurality of pixels 14 thus form a pixel region. In an example in FIG. 1, the plurality of pixels 14 are two-dimensionally arranged in a row direction and in a column direction. In other words, a plurality of rows and a plurality of columns are formed by the plurality of pixels 14. The row direction is a direction in which a row extends and is a left-right direction in FIG. 1. The column direction is a direction in which a column extends and is an up-down direction in FIG. 1.

The image sensor 101 may be a line sensor. In that case, the plurality of pixels 14 may be arranged one-dimensionally. The image sensor 101 may include a single pixel 14.

Each pixel 14 includes a photodetector 10, an amplification transistor 11, a reset transistor 12, and an address transistor 13. The photodetector 10 includes a lower electrode 50, a photoelectric conversion film 51, and an upper electrode 52. The lower electrode 50 is disposed downward of the photoelectric conversion film 51. The upper electrode 52 is disposed upward of the photoelectric conversion film 51. The lower electrode 50 may also be referred to as a pixel electrode. The upper electrode 52 may also be referred to as a counter electrode. In the present embodiment, the address transistor 13 is a row selection transistor. The upper electrode 52 is a transparent electrode.

The peripheral circuits 102 include a voltage control circuit 60. The voltage control circuit 60 applies control voltage to the upper electrodes 52 via electrode signal lines 16. Changing the control voltage can change the spectral sensitivity characteristics of the photoelectric conversion film 51.

Upon application of light to the photoelectric conversion film 51, signal charges are generated, and they are collected by the lower electrode 50. In a case where holes are used as signal charges, the control voltage is applied to the upper electrode 52 so that the potential at the lower electrode 50 may be lower than the potential at the upper electrode 52. In a case where electrons are used as signal charges, the control voltage is applied to the upper electrode 52 so that the potential at the lower electrode 50 may be higher than the potential at the upper electrode 52. A potential difference between the lower electrode 50 and the upper electrode 52 may be set by changing voltage applied to the lower electrode 50.

The lower electrode 50 is connected to the gate electrode of the amplification transistor 11. A charge storage node 24 is formed between the lower electrode 50 and the gate electrode of the amplification transistor 11. Signal charges collected by the lower electrode 50 are stored at the charge storage node 24.

Voltage in accordance with the amount of signal charges stored in the charge storage node 24 is applied to the gate electrode of the amplification transistor 11. The amplification transistor 11 amplifies the voltage applied to its gate electrode. The amplified voltage is selectively read by the address transistor 13 as signal voltage.

The source or drain of the reset transistor 12 is connected to the lower electrode 50. The reset transistor 12 resets the signal charges stored at the charge storage node 24 and resets the potentials at the gate electrode of the amplification transistor 11 and the lower electrode 50.

The imaging device 500 includes power supply wiring 21, a plurality of vertical signal lines 17, a plurality of address signal lines 26, and a plurality of reset signal lines 27. Connection of these lines to the plurality of pixels 14 enables the plurality of pixels 14 to perform the above-described operation selectively.

Specifically, the power supply wiring 21 is connected to either the sources or the drains of the amplification transistors 11. The vertical signal lines 17 are connected to either the sources or the drains of the address transistors 13. The address signal lines 26 are connected to the gate electrodes of the address transistors 13. The reset signal lines 27 are connected to the gate electrodes of the reset transistors 12.

The peripheral circuits 102 include a perpendicular scan circuit 15, a horizontal signal read circuit 20, a plurality of column signal processing circuits 19, a plurality of load circuits 18, and a plurality of differential amplifiers 22. The perpendicular scan circuit 15 is also called a row scan circuit. The horizontal signal read circuit 20 is also called a column scan circuit. The column signal processing circuits 19 are also called row signal storage circuits. The differential amplifiers 22 are also called feedback amplifiers.

The perpendicular scan circuit 15 is connected to the address signal lines 26 and the reset signal lines 27. The perpendicular scan circuit 15 selects, on a row-by-row basis, pluralities of pixels 14 disposed on the respective rows and performs read of signal voltage and reset of the potentials at the lower electrodes 50.

The power supply wiring 21 is a source follower power supply. The power supply wiring 21 supplies predetermined power supply voltage to each pixel 14.

A plurality of pixels 14 arranged on each column are electrically connected to the column signal processing circuit 19 corresponding to the column via the vertical signal line 17 corresponding to the column. The column signal processing circuits 19 are electrically connected to the horizontal signal read circuit 20.

A plurality of pixels 14 arranged on each column are electrically connected to the load circuit 18 corresponding to the column via the vertical signal line 17 corresponding to the column. The load circuit 18 and the amplification transistor 11 form a source follower circuit.

A plurality of pixels 14 arranged on each column are electrically connected to the negative input terminal of the differential amplifier 22 corresponding to the column via the vertical signal line 17 corresponding to the column. The output terminal of the differential amplifier 22 corresponding to each column is connected to the plurality of pixels 14 arranged on the column via a feedback line 23 corresponding to the column.

The perpendicular scan circuit 15 applies a row selection signal to the gate electrodes of the address transistors 13 via the address signal line 26. A row selection signal controls on and off of the address transistor 13. Upon application of a row selection signal, a row to be read is scanned and selected. Signal voltage is read from each pixel 14 arranged on the selected row to the vertical signal line 17 for the column to which the pixel 14 belongs.

The perpendicular scan circuit 15 applies a reset signal to the gate electrodes of the reset transistors 12 via the reset signal line 27. A reset signal controls on and off of the reset transistor 12. Upon application of a reset signal, a row of pixels 14 targeted for a reset operation are selected. The vertical signal line 17 transmits signal voltage read from the pixels 14 selected by the perpendicular scan circuit 15 to the column signal processing circuit 19 for the column to which the pixels 14 belong.

The column signal processing circuit 19 performs noise reduction signal processing, analog-to-digital conversion (AD conversion), and the like. The noise reduction signal processing includes, for example, correlated double sampling.

The horizontal signal read circuit 20 sequentially reads signals from the plurality of column signal processing circuits 19 to a horizontal shared signal line (not shown).

The output terminal of the differential amplifier 22 is connected to the drains of the reset transistors 12 via the feedback line 23. When the address transistor 13 and the reset transistor 12 are electrically continuous, voltage outputted from the address transistor 13 is supplied to the negative input terminal of the differential amplifier 22. In order for voltage outputted from the differential amplifier 22 and applied to the gate electrode of the amplification transistor 11 to be predetermined feedback voltage, the differential amplifier 22 performs a feedback operation. The feedback voltage is a positive voltage of 0 V or close to 0 V.

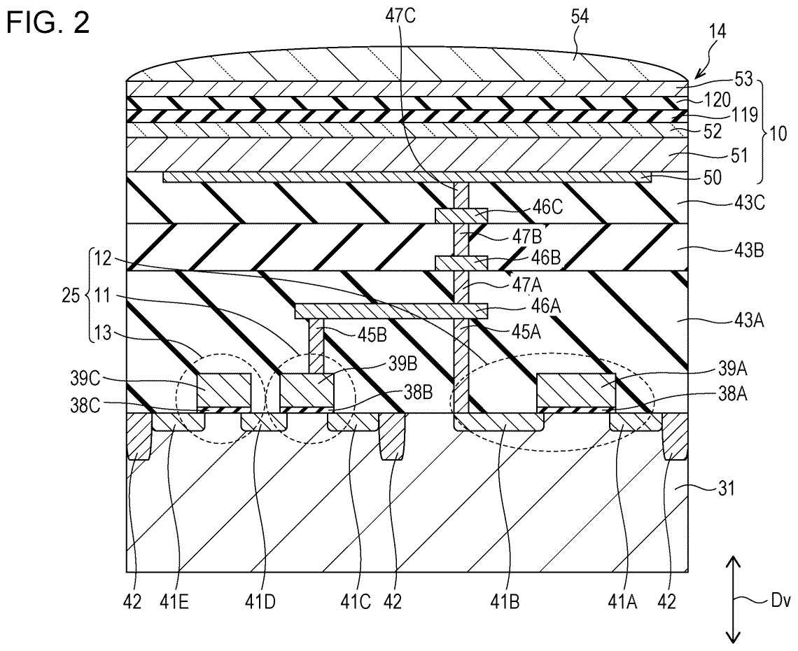

FIG. 2 is a sectional view showing the device structure of the pixel 14 according to Embodiment 1. The pixel 14 includes a semiconductor substrate 31, a charge detection circuit 25, and the photodetector 10. The semiconductor substrate 31 is, for example, a p-type silicon substrate. The charge detection circuit 25 detects signal charges captured by the lower electrode 50 and outputs signal voltage. The charge detection circuit 25 includes the amplification transistor 11, the reset transistor 12, and the address transistor 13. The charge detection circuit 25 is provided at the semiconductor substrate 31.

The amplification transistor 11 includes an n-type impurity region 41C, an n-type impurity region 41D, a gate insulating layer 38B, and a gate electrode 39B. The n-type impurity region 41C is located inside the semiconductor substrate 31 and functions as a drain. The n-type impurity region 41D is located inside the semiconductor substrate 31 and functions as a source. The gate insulating layer 38B is located on the semiconductor substrate 31. The gate electrode 39B is located on the gate insulating layer 38B.

The reset transistor 12 includes an n-type impurity region 41B, an n-type impurity region 41A, a gate insulating layer 38A, and a gate electrode 39A. The n-type impurity region 41B is located inside the semiconductor substrate 31 and functions as a drain. The n-type impurity region 41A is located inside the semiconductor substrate 31 and functions as a source. The gate insulating layer 38A is located on the semiconductor substrate 31. The gate electrode 39A is located on the gate insulating layer 38A.

The address transistor 13 includes the n-type impurity region 41D, an n-type impurity region 41E, a gate insulating layer 38C, and a gate electrode 39C. The n-type impurity region 41D is located inside the semiconductor substrate 31 and functions as a drain. The n-type impurity region 41E is located inside the semiconductor substrate 31 and functions as a source. The gate insulating layer 38C is located on the semiconductor substrate 31. The gate electrode 39C is located on the gate insulating layer 38C.

The n-type impurity region 41D is shared by the amplification transistor 11 and the address transistor 13. Thus, the amplification transistor 11 and the address transistor 13 are connected in series.

A device isolation region 42 is provided at the semiconductor substrate 31. The device isolation region 42 is provided between the pixels 14 that are adjacent to each other and is provided between the amplification transistor 11 and the reset transistor 12. The device isolation region 42 electrically isolates the adjacent pixels 14 from each other and reduces leakage of signal charges stored at the charge storage node 24.

Between the semiconductor substrate 31 and the photodetector 10, an interlayer insulating layer 43A, an interlayer insulating layer 43B, and an interlayer insulating layer 43C are stacked in this order from down to up. Embedded inside the interlayer insulating layer 43A are a contact plug 45A, a contact plug 45B, a contact plug 47A, and wiring 46A. Embedded inside the interlayer insulating layer 43B are wiring 46B and a contact plug 47B. Embedded inside the interlayer insulating layer 43C are wiring 46C and a contact plug 47C.

The contact plug 45A is connected to the n-type impurity region 41B, which is the drain of the reset transistor 12. The contact plug 45B is connected to the gate electrode 39B of the amplification transistor 11. The wiring 46A connects the contact plug 45A and the contact plug 45B to each other. In this way, the n-type impurity region 41B of the reset transistor 12 is electrically connected to the gate electrode 39B of the amplification transistor 11. Also, the wiring 46A is electrically connected to the lower electrode 50 via the contact plug 47A, the wiring 46B, the contact plug 47B, the wiring 46C, and the contact plug 47C.

The photodetector 10 is provided on the interlayer insulating layer 43C. In the photodetector 10, the photoelectric conversion film 51 is disposed between the upper electrode 52 and the lower electrode 50. The lower electrode 50 is disposed closer to the semiconductor substrate 31 than the upper electrode 52 is. Specifically, the lower electrode 50 is disposed on the interlayer insulating layer 43C.

In the present embodiment, the photoelectric conversion film 51 is an organic semiconductor. The photoelectric conversion film 51 may include one or more organic semiconductor layers. For example, the photoelectric conversion film 51 may include, in addition to a photoelectric conversion layer that generates hole-electron pairs, at least one selected from the group consisting of an electron transport layer that transports electrons, a hole transport layer that transports holes, an electron blocking layer that blocks electrons, and a hole blocking layer that blocks holes. For these organic semiconductor layers, an organic p-type semiconductor and an organic n-type semiconductor including a publicly-known material can be used.

In the present embodiment, the upper electrode 52 is transparent to light to be detected. Also, the upper electrode 52 is a conductive semiconductor. For example, the upper electrode 52 contains an indium tin oxide (ITO). The upper electrode 52 may be a transparent conductive semiconductor containing other materials.

In the present embodiment, the lower electrode 50 contains metal. For example, the metal contains at least one selected from the group consisting of aluminum and copper. The lower electrode 50 may be polysilicon doped with impurities and given conductivity.

In the example in FIG. 2, the photodetector 10 further includes an insulating film 119 and a protective film 120. The insulating film 119 covers at least part of the upper surface of the upper electrode 52. The protective film 120 covers at least part of the upper surface of the insulating film 119.

In the example in FIG. 2, the pixel 14 further includes a color filter 53 and a microlens 54. The color filter 53 is disposed on the photodetector 10. The microlens 54 is disposed on the color filter 53.

In the preset embodiment, the photoelectric conversion films 51 of the respective pixels 14 are included in a single continuous film. The upper electrodes 52 of the respective pixels 14 are included in a single continuous electrode. By contrast, the lower electrodes 50 of the respective pixels 14 are separated from one another.

The photoelectric conversion films 51 of the respective pixels 14 may be separated from one another. The upper electrodes 52 of the respective pixels 14 may be separated from one another.

The image sensor 101 of the present embodiment detects charges produced by photoelectric conversion. Specifically, the photoelectric conversion film 51 generates hole-electron pairs in accordance with the intensity of incident light. Either holes or electrons are detected as signal charges. Light incident on the photoelectric conversion film 51 is thus detected.

In a modification, the capacity of the photoelectric conversion film changes depending on the intensity of incident light, and the change is detected. Light incident on the photoelectric conversion film is thus detected. An image sensor including such a photoelectric conversion film is disclosed in, for example, International Publication No. WO2017/081847.

### Structure of the Image Sensor

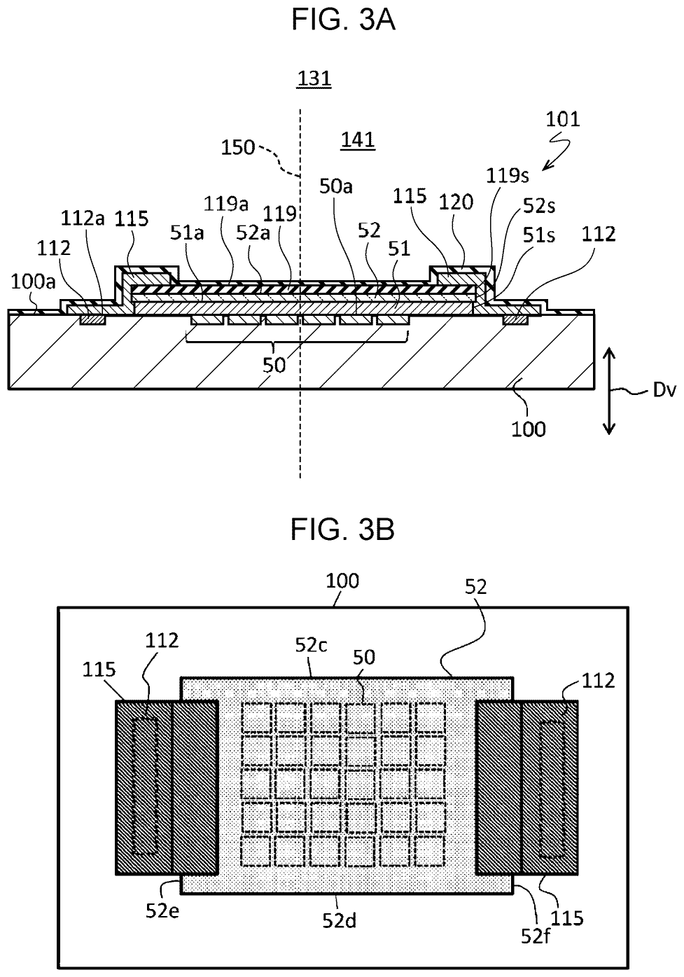

FIGS. 3A and 3B are respectively a sectional view and a top view of the image sensor 101 according to Embodiment 1. Hereinafter, the semiconductor substrate 31, the interlayer insulating layer 43A, the interlayer insulating layer 43B, and the interlayer insulating layer 43C may be referred to collectively as a substrate 100.

The image sensor 101 includes a plurality of control electrodes 112 and a plurality of connectors 115. A circuit section including the plurality of lower electrodes 50 and the plurality of control electrodes 112 is configured in the image sensor 101. The connectors 115 are part of the electrode signal lines 16.

The plurality of lower electrodes 50 are disposed on the substrate 100. The photoelectric conversion film 51 covers upper surfaces 50a of the plurality of lower electrodes 50 and an upper surface 100a of the substrate 100 from above. The upper electrode 52 covers an upper surface 51a of the photoelectric conversion film 51 from above. In the example in FIG. 3A, the upper electrode 52 covers the entire upper surface 51a of the photoelectric conversion film 51 from above. The insulating film 119 covers at least part of an upper surface 52a of the upper electrode 52 from above. The upper electrode 52 and the insulating film 119 each overlap with the plurality of lower electrodes 50 in a plan view.

The connectors 115 electrically connect the control electrodes 112 and the upper electrode 52. The connectors 115 are in contact with the control electrodes 112, the photoelectric conversion film 51, and the upper electrode 52. Specifically, each connector 115 is in contact with an upper surface 112a of the control electrode 112, a side surface 51s of the photoelectric conversion film 51, and a side surface 52s of the upper electrode 52. An upper surface 119a of the insulating film 119 has a portion not overlapping with the plurality of lower electrodes 50 in a plan view, and the connectors 115 are in contact with that portion. The area of contact between the connector 115 and the control electrode 112 may be larger than, smaller than, or the same as the area of contact between the connector 115 and the upper electrode 52.

In the present embodiment, in a plan view, the photoelectric conversion film 51, the insulating film 119, and the upper electrode 52 each have a rectangular shape. The upper electrode 52 has a side 52c, a side 52d, a side 52e, and a side 52f. In the present embodiment, the side 52c, the side 52d, the side 52e, and the side 52f are sides of the lower surface of the upper electrode 52 and the lower edges of the side surface 52s.

A first control electrode 112 is disposed near the side 52e, and a second control electrode 112 is disposed near the side 52f. A first connector 115 is in contact with the upper surface 112a of the first control electrode 112 and the side surface 52s of the upper electrode 52, and a second connector 115 is in contact with the upper surface 112a of the second control electrode 112 and the side surface 52s of the upper electrode 52. The first connector 115 and the second connector 115 electrically connect the first control electrode 112, the second control electrode 112, and the upper electrode 52. The protective film 120 covers the connectors 115, the insulating film 119, and the substrate 100 from above.

In the present embodiment, the control electrodes 112 have a light blocking property. The control electrodes 112 contain, for example, at least one selected from the group consisting of metals and metallic compounds. In one specific example, the control electrodes 112 contain at least one selected from the group consisting of titanium, titanium nitride, aluminum, silicon, copper-added aluminum (AlSiCu), copper, and tungsten. The control electrodes 112 may contain an alloy containing at least two of the materials listed in the above specific example. The control electrodes 112 may have a single-layer structure or a multilayer structure.

The connectors 115 contain, for example, at least one selected from the group consisting of metals and metallic compounds. In one specific example, the connectors 115 contain at least one selected from the group consisting of titanium, titanium nitride, aluminum, silicon, copper-added aluminum (AlSiCu), copper, tungsten, gold, silver, nickel, and cobalt. The connectors 115 may contain an alloy containing at least two of the materials listed in the above specific example. The connectors 115 may have a single-layer structure or a multilayer structure.

The insulating film 119 contains, for example, at least one selected from the group consisting of silicon oxide, silicon nitride, silicon oxynitride, organic polymer materials, and inorganic polymer materials. The insulating film 119 may be transparent to light with a wavelength to be detected by the image sensor 101. The insulating film 119 may have a single-layer structure or a multilayer structure.

The protective film 120 has insulating properties. The protective film 120 contains, for example, at least one selected from the group consisting of silicon oxide, silicon nitride, silicon oxynitride, aluminum oxide, organic polymer materials, and inorganic polymer materials. The protective film 120 may be transparent to light with a wavelength to be detected by the image sensor 101. The composition of a material contained in the protective film 120 and the composition of a material contained in the insulating film 119 may be the same as each other or different from each other. The protective film 120 may have a single-layer structure or a multilayer structure.

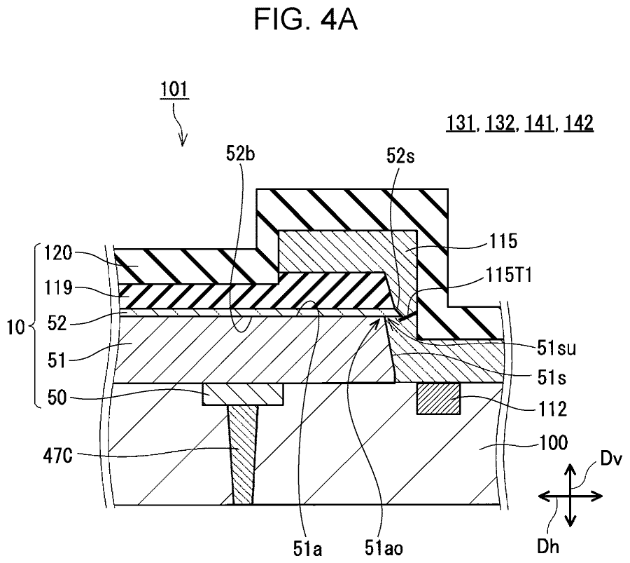

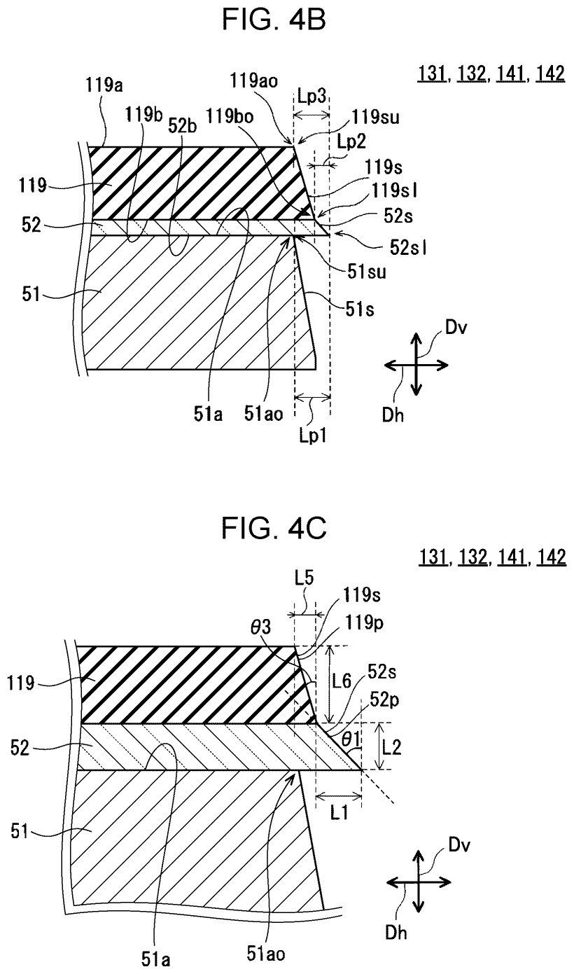

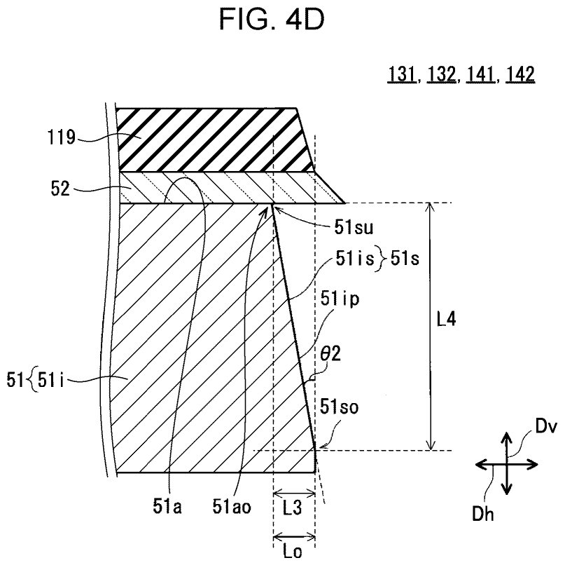

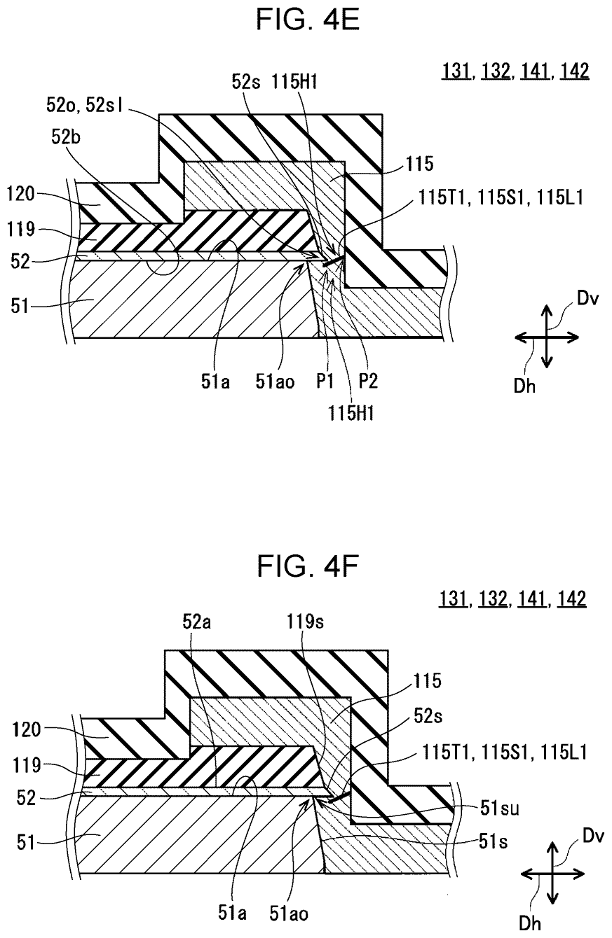

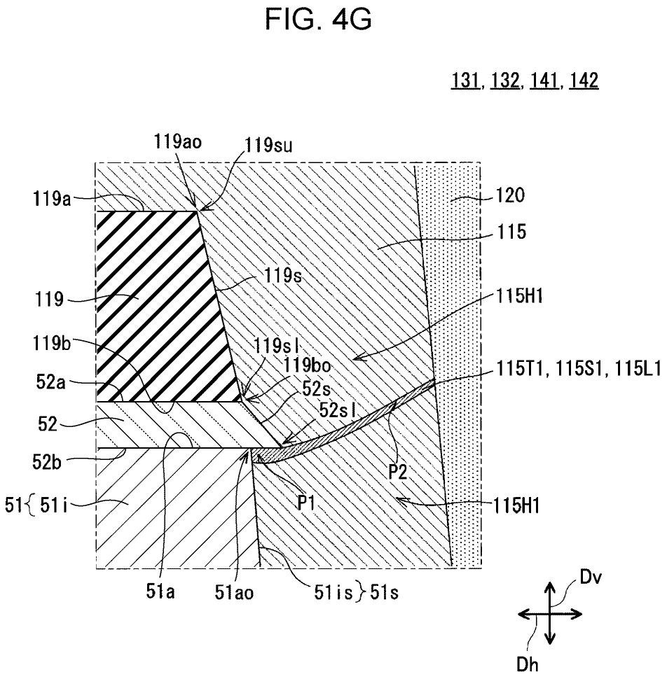

FIGS. 4A to 4G are partial sectional views of the image sensor 101 according to Embodiment 1. A further description of the image sensor 101 according to the present embodiment is given below with reference to FIGS. 4A to 4G.

The description below uses the following terms: a first section 131, a second section 132, a first partial section 141, a second partial section 142, and a penetrating straight line 150. The first section 131 and the second section 132 are each a section parallel to a perpendicular direction Dv. Specifically, the perpendicular direction Dv may be an up-down direction. The first section 131 and the second section 132 are orthogonal to each other. The imaginary penetrating straight line 150 (see FIG. 3A) extends in the perpendicular direction Dv, penetrating through the photoelectric conversion film 51 and the upper electrode 52. The first partial section 141 is one of two parts of the first section 131 divided by the penetrating straight line 150, and the second partial section 142 is one of two parts of the second section 132 divided by the penetrating straight line 150.

The following descriptions on the first section 131 are intended to state that the descriptions hold true for at least one of the two parts of the first section 131 divided by the penetrating straight line 150. Some or all of the descriptions may hold true for both of the two parts. For example, a description “on the first section 131, the upper electrode 52 extends to a position outward of an outer edge 51ao of the upper surface 51a of the photoelectric conversion film 51” means that this description holds true for at least one of the two parts. This description may hold true for both of the two parts.

Some or all of the following descriptions on the first section 131 may be applied to at least one of two parts of the second section 132 divided by the penetrating straight line 150. Thus, some or all of the descriptions may be applied to the second partial section 142 as well. Reference numerals 131 and 132 and reference numerals 141 and 142 are juxtaposed in FIG. 4A and the like for this reason. Some or all of the descriptions may be applied to both of the two parts. Also, some or all of the descriptions may be applied to all the sections and directions orthogonal to the perpendicular direction Dv.

As shown in FIG. 4A, the image sensor 101 includes the photoelectric conversion film 51, the upper electrode 52, and the connectors 115. The upper electrode 52 is located upward of the photoelectric conversion film 51. The connectors 115 supply voltage to the upper electrode 52 by electrically connecting the upper electrode 52 to a connection destination. The voltage control circuit 60 supplies voltage to the upper electrode 52 via the electrode signal lines 16 including the connectors 115. On the first section 131, the connector 115 is in contact with the side surface 51s of the photoelectric conversion film 51. This configuration makes the side surface 51s less likely to be exposed to the atmosphere, water, and the like. The connection destination may be the control electrode 112. The photoelectric conversion film 51 has a photoelectric conversion function. What is meant by the photoelectric conversion film 51 having a photoelectric conversion function is that at least part of the photoelectric conversion film 51 can perform photoelectric conversion.

As shown in FIG. 4A, on the first section 131, the upper electrode 52 extends to a position outward of the outer edge 51ao of the upper surface 51a of the photoelectric conversion film 51. This configuration may reduce current leakage. A direction orthogonal to the perpendicular direction Dv on the first section 131 is herein defined as a lateral direction Dh. On the first section 131, “outward” refers specifically to a side away from the center point of the upper surface 51a in the lateral direction Dh.

Specifically, as will be described later, a method for manufacturing the image sensor 101 may include processing the upper electrode 52 and the photoelectric conversion film 51 using dry etching. According to the above configuration, in the process of manufacturing the image sensor 101, a space where etching gas stagnates may be formed at a location which is under the upper electrode 52 and outward of the side surface of the photoelectric conversion film 51. It is difficult for new etching gas to go into the space where the etching gas stagnates. This may reduce damage on the side surface of the photoelectric conversion film due to plasma or the like during the etching. Thus, the image sensor 101 with reduced current leakage may be achieved. Also, the image sensor 101 with uniform current-voltage characteristics and favorable controllability may be achieved.

As shown in FIG. 4B, the upper surface 51a of the photoelectric conversion film 51 includes a contact surface between the photoelectric conversion film 51 and the upper electrode 52 (hereinafter referred to as a first contact surface). On the first section 131, at the same position as the first contact surface in terms of the perpendicular direction Dv, the side surface 52s of the upper electrode 52 is located outward of the side surface 51s of the photoelectric conversion film 51. What is meant by the same position as the first contact surface in terms of the perpendicular direction Dv is being at the same height as the first contact surface in reference to, for example, the surface of the substrate 100. In the example in FIG. 4B, on the first section 131, a portion of the side surface 52s which is present at the same position as the first contact surface in terms of the perpendicular direction Dv is a lower edge 52s1 of the side surface 52s. On the first section 131, a portion of the side surface 51s which is present at the same position as the first contact surface in terms of the perpendicular direction Dv is an upper edge 51su of the side surface 51s.

On the first section 131, a lower surface 52b of the upper electrode 52 may be in contact with the connector 115. This configuration is advantageous from the perspective of increasing the area of contact between the connector 115 and the upper electrode 52 and reducing electric resistance between them. Thus, delay in application of voltage to the upper electrode 52 is reduced, and isochronism in voltage change may increase. However, on the first section 131, there may be a gap between the lower surface 52b of the upper electrode 52 and the connector 115, and the lower surface 52b of the upper electrode 52 does not have to be in contact with the connector 115.

As shown in FIG. 4B, on the first section 131, the distance by which the upper electrode 52 protrudes outward from the outer edge 51ao of the upper surface 51a of the photoelectric conversion film 51 is defined as a first protruding distance Lp1. The first protruding distance Lp1 is, for example, greater than or equal to 5 nm and smaller than or equal to 50 nm. The upper electrode 52's protruding outward to this degree is suitable for reducing current leakage. The first protruding distance Lp1 may be greater than or equal to 7 nm and smaller than or equal to 40 nm. In the example in FIG. 4B, the first protruding distance Lp1 is a distance, on the first section 131, between the side surface 52s of the upper electrode 52 and the side surface 51s of the photoelectric conversion film 51, at the same position as the first contact surface in terms of the perpendicular direction Dv. Also, in the example in FIG. 4B, the first protruding distance Lp1 is a distance, on the first section 131, between the lower edge 52s1 of the side surface 52s of the upper electrode 52 and the upper edge 51su of the side surface 51s of the photoelectric conversion film 51 in terms of the lateral direction Dh.

The image sensor 101 includes the insulating film 119. The insulating film 119 is located upward of the upper electrode 52. As shown in FIG. 4B, on the first section 131, the upper electrode 52 extends to a position outward of an outer edge 119bo of a lower surface 119b of the insulating film 119. The distance by which the upper electrode 52 protrudes outward from the outer edge 119bo on the first section 131 is defined as a second protruding distance Lp2. The second protruding distance Lp2 is, for example, greater than or equal to 3 nm and smaller than or equal to 30 nm and may be greater than or equal to 4 nm and smaller than or equal to 20 nm. In the example in FIG. 4B, the second protruding distance Lp2 is a distance, on the first section 131, between the lower edge 52s1 of the side surface 52s of the upper electrode 52 and a lower edge 119s1 of a side surface 119s of the insulating film 119 in terms of the lateral direction Dh.

As shown in FIG. 4B, on the first section 131, the upper electrode 52 extends to a position outward of an outer edge 119ao of the upper surface 119a of the insulating film 119. The distance by which the upper electrode 52 protrudes outward from the outer edge 119ao on the first section 131 is defined as a third protruding distance Lp3. The third protruding distance Lp3 is, for example, greater than or equal to 5 nm and smaller than or equal to 50 nm and may be greater than or equal to 7 nm and smaller than or equal to 40 nm. In the example in FIG. 4B, the third protruding distance Lp3 is a distance, on the first section 131, between the lower edge 52s1 of the side surface 52s of the upper electrode 52 and an upper edge 119su of the side surface 119s of the insulating film 119 in terms of the lateral direction Dh.

In the example in FIG. 4B, the first protruding distance Lp1 is longer than the second protruding distance Lp2. However, the first protruding distance Lp1 may be the same as the second protruding distance Lp2 or may be shorter than the second protruding distance Lp2. The ratio of the first protruding distance Lp1 to the second protruding distance Lp2, Lp1/Lp2, is, for example, greater than or equal to 1 and smaller than or equal to 5 and may be greater than or equal to 1.1 and smaller than or equal to 3.

In the example in FIG. 4B, the third protruding distance Lp3 is longer than the second protruding distance Lp2. However, the third protruding distance Lp3 may be the same as the second protruding distance Lp2. The ratio of the third protruding distance Lp3 to the second protruding distance Lp2, Lp3/Lp2, is, for example, greater than or equal to 1.1 and smaller than or equal to 6 and may be greater than or equal to 1.2 and smaller than or equal to 4.

In the example in FIG. 4B, the third protruding distance Lp3 is longer than the first protruding distance Lp1. However, the third protruding distance Lp3 may be the same as the first protruding distance Lp1 or may be shorter than the first protruding distance Lp1. The ratio of the third protruding distance Lp3 to the first protruding distance Lp1, Lp3/Lp1, is, for example, greater than or equal to 0.6 and smaller than or equal to 3 and may be greater than or equal to 0.8 and smaller than or equal to 2.5.

As shown in FIG. 4C, on the first section 131, the side surface 52s of the upper electrode 52 includes a first tapered portion 52p spreading outward from up to down. This configuration is advantageous from the perspective of increasing the area of contact between the side surface 52s of the upper electrode 52 and the connector 115 and reducing electric resistance between them in a case where the side surface 52s of the upper electrode 52 is in contact with the connector 115.

An angle θ1 of the first tapered portion 52p relative to the perpendicular direction Dv is greater than 0° and smaller than 90°. The angle θ1 is, for example, greater than 0° and smaller than or equal to 20° and may be greater than 0° and smaller than or equal to 100.

The angle θ1 is described. The distance between the upper edge and the lower edge of the first tapered portion 52p in terms of the lateral direction Dh is defined as a first distance L1. The distance between the upper edge and the lower edge of the first tapered portion 52p in terms of the perpendicular direction Dv is defined as a second distance L2. The angle θ1 is the arctangent of the ratio of the first distance L1 to the second distance L2, L1/L2. As is understood from this description, the angle θ1 may be determined even if the first tapered portion 52p is curved.

As shown in FIG. 4C, on the first section 131, the side surface 119s of the insulating film 119 includes a third tapered portion 119p spreading outward from up to down. An angle θ3 of the third tapered portion 119p relative to the perpendicular direction Dv is greater than 0° and smaller than 90°. The angle θ3 is, for example, greater than 0° and smaller than or equal to 20° and may be greater than 0° and smaller than or equal to 100.

The angle θ3 is described. The distance between the upper edge and the lower edge of the third tapered portion 119p in terms of the lateral direction Dh is defined as a fifth distance L5. The distance between the upper edge and the lower edge of the third tapered portion 119p in terms of the perpendicular direction Dv is defined as a sixth distance L6. The angle θ3 is the arctangent of the ratio of the fifth distance L5 to the sixth distance L6, L5/L6.

In the example in FIG. 4C, the angle θ3 is smaller than the angle θ1. However, the angle θ3 may be the same as the angle θ1 or may be greater than the angle θ1.

As shown in FIG. 4D, on the first section 131, the side surface 51s of the photoelectric conversion film 51 includes a second tapered portion 51ip spreading outward from up to down. In this case, the upper side of the second tapered portion 51ip may be on the inner side. This makes it easier to achieve the configuration in which the upper electrode 52 extends to a position outward of the outer edge 51ao of the upper surface 51a of the photoelectric conversion film 51.

In the example in FIG. 4D, the photoelectric conversion film 51 includes a photoelectric conversion layer 51i. On the first section 131, a side surface 51is of the photoelectric conversion layer 51i includes the second tapered portion 51ip described above. Specifically, in the example in FIG. 4D, the entire photoelectric conversion film 51 is the photoelectric conversion layer 51i. Hereinafter, the side surface of the photoelectric conversion layer 51i is referred to as the side surface 51is. The side surface 51is is included in the side surface 51s. In the example in FIG. 4D, the entire side surface 51s is the side surface 51is.

An angle θ2 of the second tapered portion 51ip relative to the perpendicular direction Dv is greater than 0° and smaller than 90°. The angle θ2 is, for example, greater than 0° and smaller than or equal to 20° and may be greater than 0° and smaller than or equal to 10°.

The angle θ2 is described. The distance between the upper edge and the lower edge of the second tapered portion 51ip in terms of the lateral direction Dh is defined as a third distance L3. The distance between the upper edge and the lower edge of the second tapered portion 51ip in terms of the perpendicular direction Dv is defined as a fourth distance L4. The angle θ2 is the arctangent of the ratio of the third distance L3 to the fourth distance L4, L3/L4.

As shown in FIG. 4D, on the first section 131, the upper edge 51su of the side surface 51s of the photoelectric conversion film 51 is located inward of an outer edge 51so of the same. This makes it easier to achieve the configuration in which the upper electrode 52 extends to a position outward of the outer edge 51ao of the upper surface 51a of the photoelectric conversion film 51.

On the first section 131, the distance between the upper edge 51su and the outer edge 51so of the side surface 51s of the photoelectric conversion film 51 in terms of the lateral direction Dh is defined as a drawn-back distance Lo. The drawn-back distance Lo is, for example, greater than or equal to 5 nm and smaller than or equal to 50 nm and may be greater than or equal to 7 nm and smaller than or equal to 40 nm. In the example in FIG. 4D, the drawn-back distance Lo is the same as the third distance L3. The drawn-back distance Lo may be different from the third distance L3.

As shown in FIG. 4E, on the first section 131, a first crack 115T1 extends. On the first section 131, the first crack 115T1 includes a first part P1 and a second part P2. On the first section 131, the first part P1 is located inward and downward of an outer edge 52o of the upper electrode 52. On the first section 131, the second part P2 is located outward and upward of the outer edge 52o. On the first section 131, the second part P2 is located inside the connector 115. The first crack 115T1 in such a configuration may mitigate stress in the connector 115. In the above descriptions, in the example in FIG. 4E, “the outer edge 52o of the upper electrode 52” may be read as “the outer edge of the lower surface 52b of the upper electrode 52” or the “lower edge 52s1 of the side surface 52s of the upper electrode 52.” In the example in FIG. 4E, on the first section 131, the first part P1 is located outward of the outer edge 51ao of the upper surface 51a of the photoelectric conversion film 51. On the first section 131, the first part P1 may be located inside the connector 115. FIG. 4G shows a specific example of the first crack 115T1 according to Embodiment 1.

A description is given as to the “crack” now. The crack may be provided between a plurality of portions of the same material or between a plurality of portions of different materials. For example, the crack may be provided between a portion of the connector 115 and another portion of the connector 115. The crack may be provided between the upper electrode 52 and the connector 115. The crack may be provided between the photoelectric conversion film 51 and the connector 115.

The first crack 115T1 may include at least one of a first gap 115S1 or a first low density portion 115L1. On the first section 131, the connector 115 may be exposed in the first gap 115S1. On the first section 131, the first low density portion 115L1 may be sandwiched adjacently between two first high density portions 115H1. On the first section 131, the first low density portion 115L1 may be a seam between the two first high density portions 115H1. The density of the first low density portion 115L1 is lower than that of the two first high density portions 115H1. The first low density portion 115L1 and the two first high density portions 115H1 are portions included in the connector 115. In this context, the density refers to a mass per unit volume.

On the first section 131, the first crack 115T1 may extend continuously. On the first section 131, the first crack 115T1 may extend upward as it goes outward. On the first section 131, the first crack 115T1 may have a relatively thick portion and a relatively thin portion. For example, on the first section 131, the first gap 11551 may have a portion thicker than the first low density portion 115L1. Also, for example, on the first section 131, the first part P1 may be thicker than the second part P2. On the first section 131, the first crack 115T1 may or may not be exposed to or in contact with the lower surface 52b of the upper electrode 52.

In a first specific example, on the first section 131, the first gap 11551 includes the first part P1, and the first low density portion 115L1 includes the second part P2. On the first section 131, the lower surface 52b of the upper electrode 52 is exposed in the first gap 11551. On the first section 131, one of the two first high density portions 115H1 is in contact with the side surface 52s of the upper electrode 52.

In a second specific example, on the first section 131, the first low density portion 115L1 includes the first part P1 and the second part P2. On the first section 131, the first low density portion 115L1 is in contact with the lower surface 52b of the upper electrode 52. On the first section 131, one of the two first high density portions 115H1 is in contact with the side surface 52s of the upper electrode 52.

When the image sensor 101 according to this example is seen three-dimensionally, the first crack 115T1 lies in the shape of a strip. In a plan view, the first crack 115T1 extends along the side surface 51s of the photoelectric conversion film 51.

In the example in FIG. 4E, the following descriptions can also be applied to the connector 115. On the first section 131, the connector 115 includes a first connection portion, a second connection portion, and a strip-shaped first seam connecting the upper surface of the first connection portion and the lower surface of the second connection portion. On the first section 131, the upper surface of the first connection portion includes a portion located inward and downward of the outer edge 52o of the upper electrode 52 and a portion located outward and upward of the outer edge 52o. On the first section 131, the upper surface of the first connection portion may extend upward as it goes outward. The first connection portion may correspond to one of the two first high density portions 115H1. The second connection portion may correspond to the other one of the two first high density portions 115H1. The first seam may correspond to the first low density portion 115L1.

As shown in FIG. 4F, on the first section 131, the connector 115, the insulating film 119, and the upper electrode 52 are disposed in this order from up to down. On the first section 131, the upper surface 52a of the upper electrode 52 is spaced away from the connector 115. On the first section 131, the upper surface 52a and the connector 115 are not in contact with each other. This configuration may be obtained by a manufacturing method in which a material for the connector 115 is deposited from above by sputtering or the like with the insulating film 119 used as a mask.

As shown in FIG. 4F, on the first section 131, the side surface 119s of the insulating film 119 and the side surface 52s of the upper electrode 52 are continuously linked to each other continuously. The upper electrode 52 and the insulating film 119 in this configuration are formed by etching. Specifically, in the example in FIG. 4F, on the first section 131, the insulating film 119 is in contact with the upper electrode 52 from above, and the side surface 119s of the insulating film 119 and the side surface 52s of the upper electrode 52 are continuously linked to each other from up to down.

As shown in FIG. 4A, on the first section 131, the connector 115 is in contact with the side surface 52s of the upper electrode 52. According to this configuration, the upper electrode 52 and the connector 115 can be electrically connected to each other by the side surface 52s.

As shown in FIG. 4A, the control electrode 112 is located downward of the photoelectric conversion film 51. The connector 115 is in contact with the control electrode 112.

In a typical example, the composition of a material contained in the upper electrode 52 is different from that of a material contained in the connector 115.

In a typical example, the electrical conductivity of a material contained in the connector 115 is higher than that of a material contained in the upper electrode 52. This configuration makes it easier to electrically connect the upper electrode 52 to a connection destination.

In a typical example, the transmittance of a material contained in the upper electrode 52 to light with a predetermined wavelength is higher than that of a material contained in the connector 115. This configuration makes it easier for the photoelectric conversion film 51 to be supplied with light via the upper electrode 52. The predetermined wavelength may be a wavelength to be imaged by the image sensor 101. For example, the predetermined wavelength may be 400 nm, 500 nm, 600 nm, 700 nm, 800 nm, 900 nm, or 1000 nm. Over the entire range of wavelengths from greater than or equal to 400 nm and smaller than or equal to 1000 nm, the light transmittance of the material contained in the upper electrode 52 may be higher than that of the material contained in the connector 115.

In the present embodiment, the imaging device 500 includes the image sensor 101 and the peripheral circuits 102. The peripheral circuits 102 control the image sensor 101. Method for Manufacturing the Image Sensor

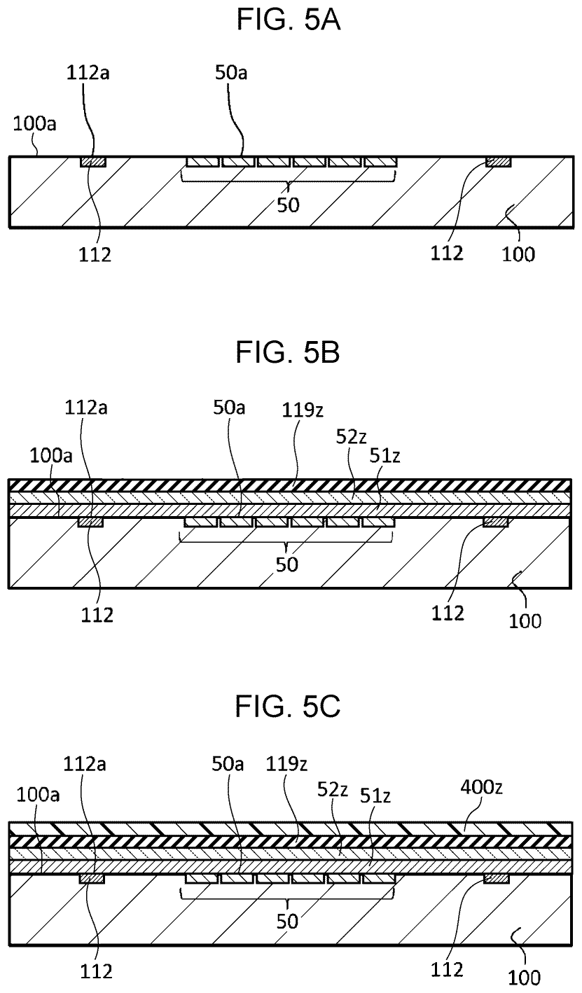

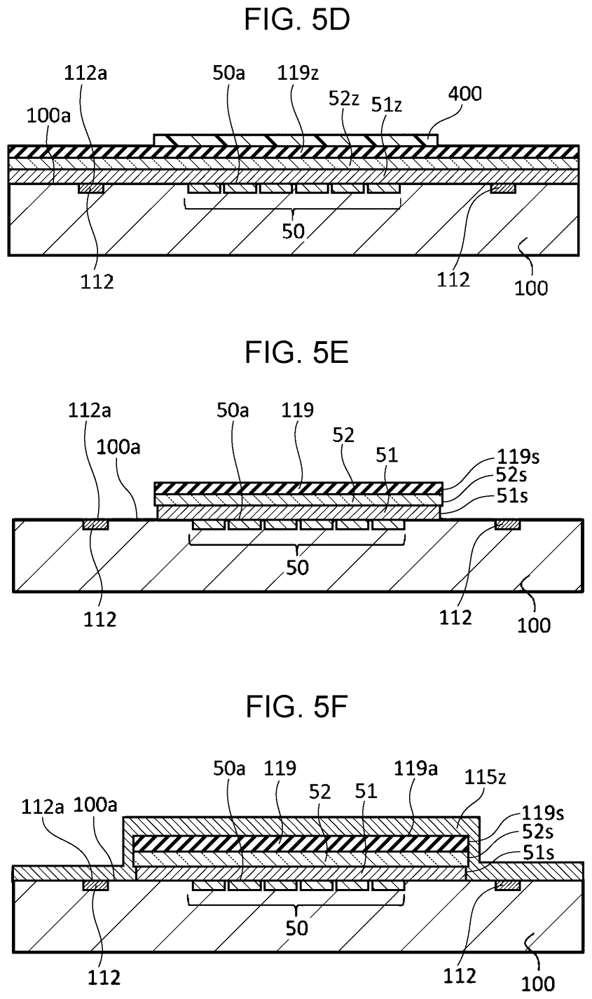

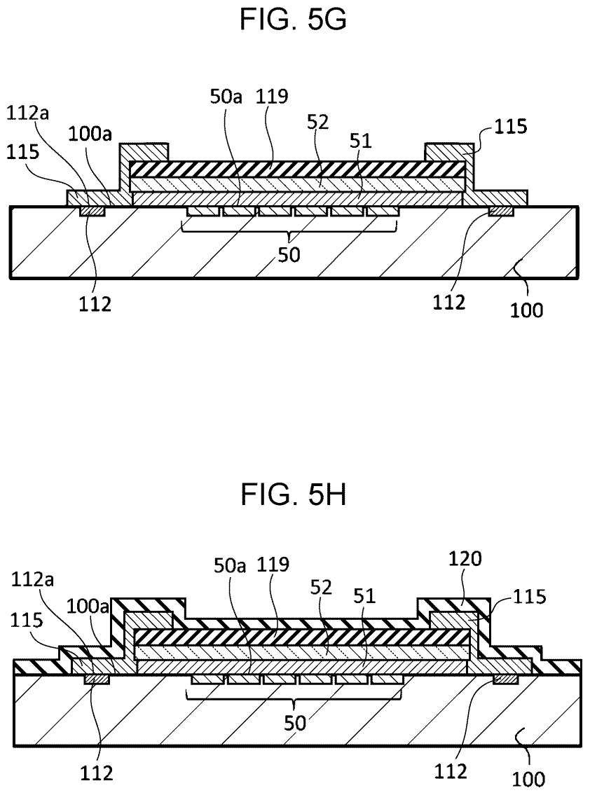

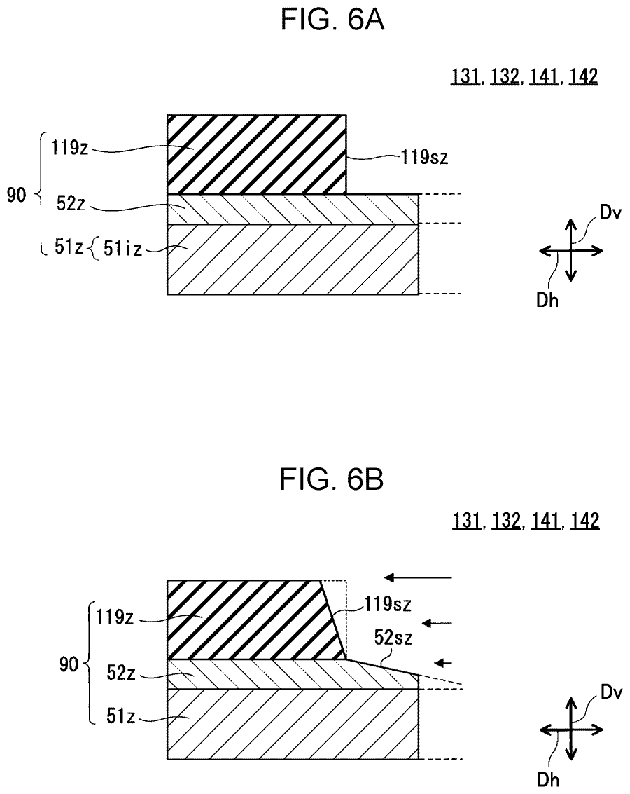

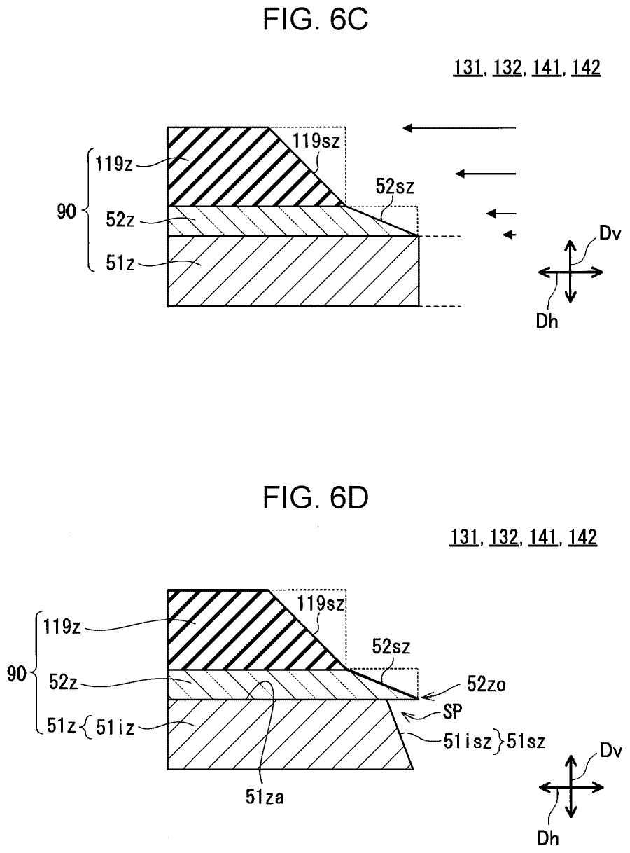

FIGS. 5A to 5H are sectional views showing the process of manufacturing the image sensor 101 according to Embodiment 1. FIGS. 6A to 6D are diagrams illustrating how the insulating film 119, the upper electrode 52, and the photoelectric conversion film 51 are dry-etched in Embodiment 1. A method for manufacturing the image sensor 101 according to the present embodiment is described below with reference to FIGS. 5A to 5H and 6A to 6D.

### (A) Step of Preparing a Circuit Part

First, as shown in FIG. 5A, a circuit part is prepared. Specifically, a structure such that a plurality of lower electrodes 50 and a plurality of control electrodes 112 are disposed on the substrate 100 is prepared. The upper surface of this structure includes the upper surface 100a of the substrate 100, the upper surfaces 50a of the lower electrodes 50, and the upper surfaces 112a of the control electrodes 112. A region of this structure below the lower electrode 50 is as shown in FIG. 2. The structure shown in FIGS. 5A and 2 can be manufactured using a publicly-known semiconductor device manufacturing method.

### (B) Step of Disposing a Photoelectric Conversion Film

Next, as shown in FIG. 5B, a photoelectric conversion film 51z is disposed to cover at least the lower electrodes 50 from above. The photoelectric conversion film 51z can be disposed using, for example, spin coating, inkjet, die coating, spray coating, vacuum deposition, screen printing, or the like. The photoelectric conversion film 51z disposed in this step is later processed into the photoelectric conversion film 51.

As described earlier, in the present embodiment, the photoelectric conversion film 51 includes the photoelectric conversion layer 51i. The photoelectric conversion film 51z includes a photoelectric conversion layer 51iz (see FIG. 6D) to be processed into the photoelectric conversion layer 51i. The side surface of the photoelectric conversion layer 51iz is hereinafter referred to as a side surface 51isz. The side surface 51isz is included in a side surface 51sz of the photoelectric conversion film 51z.

### (C) Step of Disposing the Upper Electrode

Next, as shown in FIG. 5B, an upper electrode 52z is disposed to cover the photoelectric conversion film 51z from above. Specifically, the upper electrode 52z is disposed to overlap with the plurality of lower electrodes 50 in a plan view. the upper electrode 52z can be disposed using, for example, sputtering. The upper electrode 52z disposed in this step is later processed into the upper electrode 52.

### (D) Step of Disposing the Insulating Film

Next, as shown in FIG. 5B, an insulating film 119z is disposed to cover the upper electrode 52z from above. Specifically, the insulating film 119z is disposed to overlap with the plurality of lower electrodes 50 in a plan view. The insulating film 119z can be disposed using, for example, atomic layer deposition (ALD), chemical vapor deposition (CVD), sputtering, or the like. The insulating film 119z disposed in this step is later processed into the insulating film 119.

### (E) Step of Pattering

Next, patterning is performed to remove part of the photoelectric conversion film 51z, part of the upper electrode 52z, and part of the insulating film 119z. As a result, the photoelectric conversion film 51z, the upper electrode 52z, and the insulating film 119z are processed into the photoelectric conversion film 51, the upper electrode 52, and the insulating film 119, respectively. A specific description of the patterning is given below with reference to FIGS. 5C to 5E.

First, a photosensitive resist 400z is disposed on the insulating film 119z shown in FIG. 5C. The resist 400z can be disposed using, for example, spin coating. Next, the resist 400z is exposed to light and developed using a photo mask. As a result, the resist 400z is processed into a resist mask 400. A structure such that the resist mask 400 is disposed on the insulating film 119z is thus obtained, as shown in FIG. 5D.

Next, the insulating film 119z is etched using the resist mask 400. Next, the resist mask 400 is removed. Next, with the insulating film 119z used as a mask, the upper electrode 52z is etched. Next, with the upper electrode 52z used as a mask, the photoelectric conversion film 51z is etched. In the present embodiment, the etching of the insulating film 119z, the etching of the upper electrode 52z, and the etching of the photoelectric conversion film 51z are dry etching.

Dry etching of the above is described in detail below. In the following description, an etching gas for dry etching of the insulating film 119z, an etching gas for dry etching of the upper electrode 52z, and an etching gas for dry etching of the photoelectric conversion film 51z are called a first etching gas, a second etching gas, and a third etching gas, respectively.

As is understood from the above descriptions, a structure 90 including the insulating film 119z, the upper electrode 52z, and the photoelectric conversion film 51z is fabricated. Flows of the first to third etching gases are formed, flowing from a position upward of the structure 90 toward the structure 90. For example, a chamber for etching has a location where the structure 90 is to be disposed. Providing an inflow port for the first to third etching gases at a position upward of this location allows the above-described flows to be formed.

Etching conditions, such as the compositions of the first to third etching gases, the pressure inside the chamber, and bias voltage applied to the substrate 100 in dry etching, may be selected appropriately depending on, e.g., the materials of the insulating film 119z, the upper electrode 52z, and the photoelectric conversion film 51z.

### <Dry Etching of the Insulating Film 119z Using the First Etching Gas>

Dry etching of the insulating film 119z using the first etching gas is performed with the resist mask 400 being disposed on a center portion of the structure 90. This dry etching progresses from up to down, grinding a side portion of the insulating film 119z. After this dry etching, the resist mask 400 is removed.

The first etching gas etches the insulating film 119z and does not substantially etch the upper electrode 52z. For this reason, as a result of the dry etching using the first etching gas, a side portion of the insulating film 119z is ground, while the upper electrode 52z is substantially not ground, as shown in FIG. 6A.

The dry etching using the first etching gas is anisotropic etching. Thus, a side surface 119sz substantially extending in the perpendicular direction Dv is formed at the insulating film 119z.

### <Dry Etching of the Upper Electrode 52z Using the Second Etching Gas>

The dry etching using the second etching gas is performed using the insulating film 119z after the dry etching using the first etching gas as a mask. The dry etching using the second etching gas progresses from up to down, grinding a side portion of the upper electrode 52z.

The second etching gas etches not only the upper electrode 52z but also the insulating film 119z and does not substantially etch the photoelectric conversion film 51z. For this reason, as a result of the dry etching using the second etching gas, a side portion of the insulating film 119z and a side portion of the upper electrode 52z are ground, while the photoelectric conversion film 51z is substantially not ground, as shown in FIGS. 6B and 6C.

FIG. 6C shows a state later than FIG. 6B in time. FIGS. 6B and 6C depict a plurality of arrows directed from right to left. The arrows at respective locations in the perpendicular direction Dv schematically show the lengths of time for which the side surface of the structure 90 is exposed to the second etching gas at those respective positions. The longer the arrow, the longer the exposure time. As is understood from FIGS. 6B and 6C, the exposure time is longer at upper locations in the insulating film 119z and the upper electrode 52z. In combination of this point and the fact that the dry etching using the second etching gas is isotropic etching, the side surface 119sz and a side surface 52sz both including a tapered portion spreading outward from up to down are formed at the insulating film 119z and the upper electrode 52z, respectively.

### <Dry Etching of the Photoelectric Conversion Film 51z Using the Third Etching Gas>

Dry etching using the third etching gas is performed using the upper electrode 52z after the dry etching using the second etching gas as a mask. The dry etching using the third etching gas progresses from up to down, grinding a side portion of the photoelectric conversion film 51z.

The third etching gas etches the photoelectric conversion film 51z, and meanwhile, does not substantially etch the insulating film 119z or the upper electrode 52z. Thus, as a result of the dry etching using the third etching gas, as shown in FIG. 6D, a side portion of the photoelectric conversion film 51z is ground, while the insulating film 119z and the upper electrode 52z are not substantially ground.

In the photoelectric conversion film 51z, the side surface 51sz is exposed to the third etching gas for a longer time at an upper location in the photoelectric conversion film 51z. In combination of this and the fact that the dry etching using the third etching gas is isotropic etching, the side surface 51sz including a tapered portion spreading outward from up to down is formed at the photoelectric conversion film 51z.

During the dry etching using the third etching gas, a space SP where the side surface 51sz of the photoelectric conversion film 51z is exposed is formed at a location downward of the upper electrode 52z and outward of the photoelectric conversion film 51z. The third etching gas stagnates in the space SP. Thus, it is less likely for fresh etching gas to go around into the space SP from a location upward of the upper electrode 52z. This makes it possible to reduce damage due to plasma or the like on the side surface 51sz during the dry etching and to grind the photoelectric conversion film 51z from outside. Thus, the image sensor 101 with reduced current leakage may be manufactured.

During the dry etching using the third etching gas, an upper surface 51za of the photoelectric conversion film 51z is covered by the insulating film 119z. Thus, during the manufacture of the image sensor 101, the side surface 51sz is the only part of the photoelectric conversion film 51z that is exposed. This may help prevent the photoelectric conversion film 51z from deteriorating by coming into contact with oxygen, ozone, moisture, or the like.

In one specific example, the insulating film 119z is a multilayer film including a lower layer made of aluminum oxide (AlO) and an upper layer made of silicon oxynitride (SiON). The upper electrode 52z contains indium tin oxide (ITO). The photoelectric conversion film 51z contains an organic material. The first etching gas contains a perfluorinated compound (PFC) or more specifically perfluoromethane (CF₄). The second etching gas contains boron trichloride (BCl₃). The third etching gas contains oxygen (O₂). A reaction between the organic material in the photoelectric conversion film 51z and oxygen in the third etching gas produces carbon oxide, and thereby, the dry etching of the photoelectric conversion film 51z using the third etching gas progresses. According to this specific example, the insulating film 119, the upper electrode 52, and the photoelectric conversion film 51 in the shapes described with reference to FIGS. 3A to 4G may be obtained. These points apply to Embodiments 2 to 4 to be described later as well.

The insulating film 119z the side portion of which has been ground by the dry etching using the first etching gas and the dry etching using the second etching gas may be the insulating film 119. The upper electrode 52z the side portion of which has been ground by the dry etching using the second etching gas may be the upper electrode 52. The photoelectric conversion film 51z the side portion of which has been ground by the dry etching using the third etching gas may be the photoelectric conversion film 51. Reference numerals 119, 52, 51 are used in the descriptions related to FIGS. 5E to 5H.

### (F) Step of Disposing the Connectors 115

Next, the connectors 115 are disposed. Specifically, the connectors 115 are disposed to electrically connect the upper electrode 52 to the control electrodes 112 and to be in contact with the side surface 51s of the photoelectric conversion film 51. The step of disposing the connectors 115 is described below in concrete terms with reference to FIGS. 5F and 5G.

First, as shown in FIG. 5F, a connector 115z is disposed to cover the upper surface 119a of the insulating film 119, the side surface 119s of the insulating film 119, the side surface 52s of the upper electrode 52, the side surface 51s of the photoelectric conversion film 51, and the upper surfaces 112a of the control electrodes 112. In the present embodiment, the connector 115z is a metal or a metallic compound. For example, a film of the connector 115z is formed by deposition from up to down using sputtering, vacuum deposition, or the like.

A resist mask (not shown) is disposed on the connector 115z. The resist mask is disposed so as not to overlap with the plurality of lower electrodes 50 in a plan view. The connector 115z is etched using the resist mask. As a result, the connector 115z is processed into the connectors 115, as shown in FIG. 5G.

As is understood from the above descriptions, the “(E) Step of Patterning” yields a state where the upper electrode 52 extends to a position outward of the outer edge 51ao of the upper surface 51a of the photoelectric conversion film 51. The first crack 115T1 shown in FIG. 4E and the like can be formed by execution of the “(F) Step of Disposing the Connectors” in this state. Specifically, because the upper electrode 52 extends to a position outward of the outer edge 51ao, the continuity of the film formed by deposition of the connector 115z from up to down may be disconnected. The first crack 115T1 may be formed due to this disconnection.

### (G) Step of Disposing the Protective Film

Next, as shown in FIG. 5H, the protective film 120 is disposed to cover the connectors 115 and the insulating film 119. Note that the protective film 120 does not have to be disposed.

As is understood from the above descriptions, the method for manufacturing the image sensor 101 may include first to third steps. In the first step, the structure 90 is obtained. The structure 90 includes the upper electrode 52z and the photoelectric conversion film 51z in this order from up to down. In the second step, dry etching is performed. In the dry etching, an etching gas that etches the photoelectric conversion film 51z at a higher rate than the upper electrode 52z is used. In the dry etching, the side surface 51sz is thereby ground, forming the space SP which is located inward and downward of the outer edge of the upper electrode 52z and which is where the side surface 51sz of the photoelectric conversion film 51z is exposed. After the dry etching, the third step is performed. In the third step, the connector 115z is disposed to electrically connect the upper electrode 52z to a connection destination and to be in contact with the side surface 51sz of the photoelectric conversion film 51z. According to this manufacturing method, the image sensor 101 can be manufactured in which the upper electrode 52 extends to a position outward of the outer edge 51ao of the upper surface 51a of the photoelectric conversion film 51. Specifically, in the dry etching, a flow of etching gas coming from a location upward of the upper electrode 52z toward a location downward of the upper electrode 52z is formed. The photoelectric conversion film 51z contains an organic material, and the etching gas contains oxygen. Dry etching may travel in a direction from up to down and in a direction from outside to inside. The dry etching may be isotropic dry etching.

Some other embodiments are described below. In the following descriptions, elements that are common between the embodiment already described and an embodiment to be described later may be denoted by the same reference numerals, and their descriptions may be omitted. Descriptions related to the embodiments may be applied to one another unless the application creates technical contradiction. The embodiments may be combined with one another unless it creates technical contradiction.

### Embodiment 2

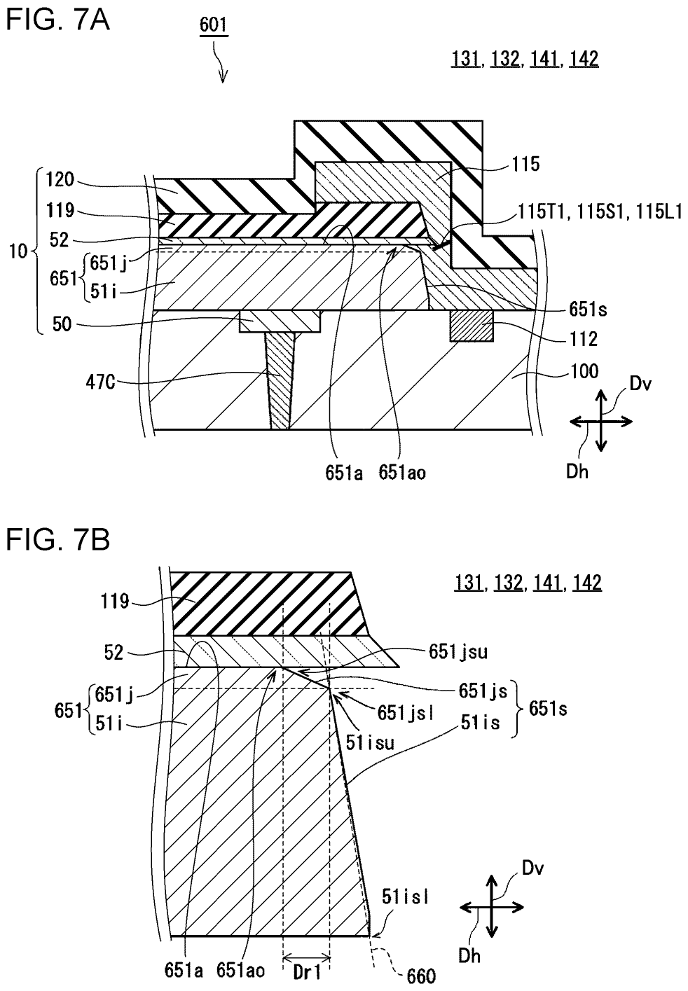

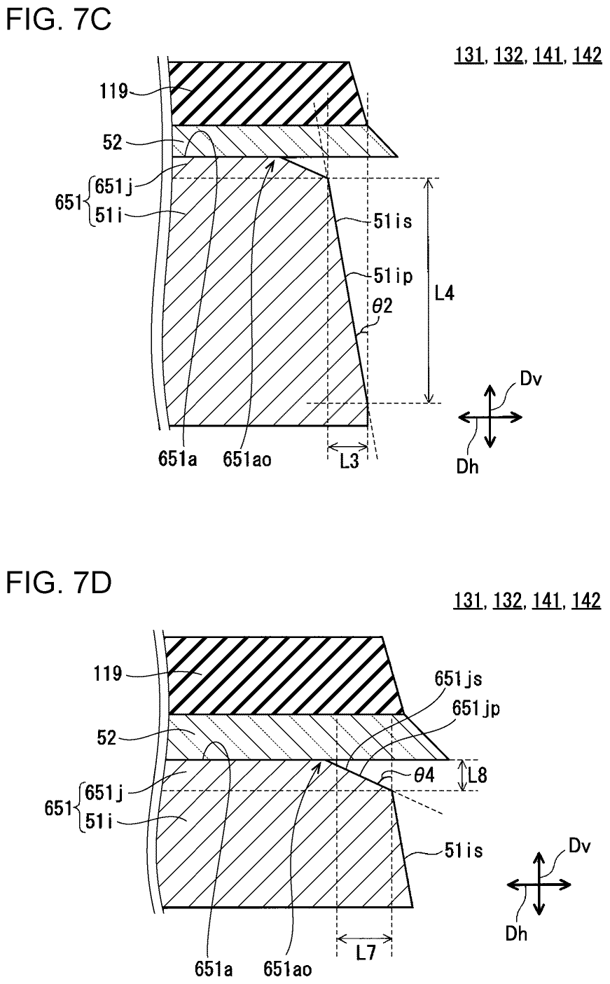

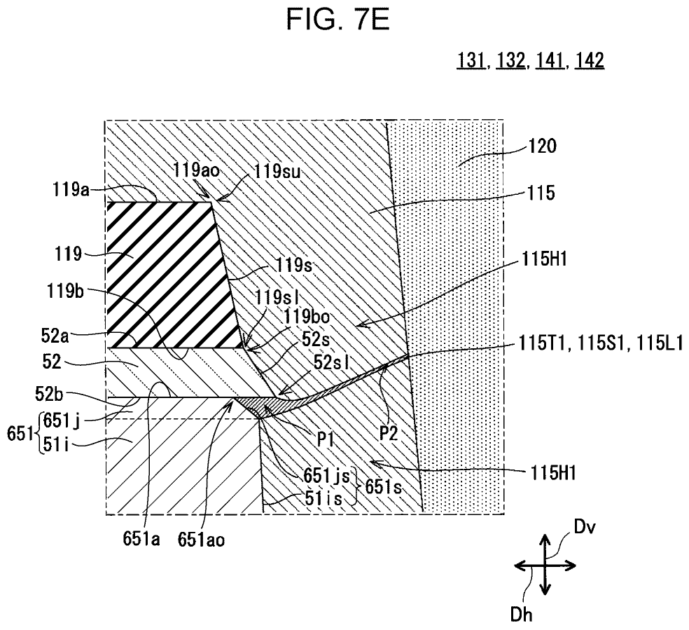

FIGS. 7A to 7E are partial sectional views of an image sensor 601 according to Embodiment 2. In the image sensor 601, a photoelectric conversion film 651 includes the photoelectric conversion layer 51i and an upper layer 651j. The upper layer 651j is located upward of the photoelectric conversion layer 51i. Hereinafter, the side surface of the photoelectric conversion film 651 and the side surface of the upper layer 651j are referred to as a side surface 651s and a side surface 651js, respectively. The side surface 651s includes the side surface 51is and the side surface 651js.

As shown in FIG. 7B, on the first section 131, a straight line including an upper edge 51isu and a lower edge 51isl of the side surface 51is of the photoelectric conversion layer 51i is defined as a reference straight line 660. On the first section 131, the side surface 651js of the upper layer 651j is located inward of the reference straight line 660. Thus, the side surface 651js is located inward of the side surface 51is. This makes it easier to achieve a configuration in which the upper electrode 52 extends to a position outward of an outer edge 651ao of an upper surface 651a of the photoelectric conversion film 651. Also, because the side surface 651js is located inward of the side surface 51is, it is easier for the photoelectric conversion film 651 to have a round edge, which facilitates reduction of concentration of an electric field.

As shown in FIG. 7B, on the first section 131, an upper edge 651jsu of the side surface 651js of the upper layer 651j is located more inward than a lower edge 651jsl of the same. The distance between the upper edge 651jsu and the lower edge 651jsl in terms of the lateral direction Dh is defined as a first retraction distance Dr1. The first retraction distance Dr1 is, for example, greater than or equal to 5 nm and smaller than or equal to 40 nm and may be greater than or equal to 10 nm and smaller than or equal to 30 nm.

As shown in FIG. 7D, on the first section 131, the side surface 651js of the upper layer 651j includes a fourth tapered portion 651jp spreading outward from up to down. In this case, the upper side of the fourth tapered portion 651jp may be more inward than the lower side of the same. This makes it easier to achieve a configuration in which the upper electrode 52 extends to a position outward of the outer edge 651ao of the upper surface 651a of the photoelectric conversion film 651. An angle θ4 of the fourth tapered portion 651jp relative to the perpendicular direction Dv is greater than 0° and smaller than 90°. The angle θ4 is, for example, greater than or equal to 250 and smaller than or equal to 65° and may be greater than or equal to 350 and smaller than or equal to 60°.

The angle θ4 is described. The distance between the upper edge and the lower edge of the fourth tapered portion 651jp in terms of the lateral direction Dh is defined as a seventh distance L7. The distance between the upper edge and the lower edge of the fourth tapered portion 651jp in terms of the perpendicular direction Dv is defined as an eighth distance L8. The angle θ4 is the arctangent of the ratio of the seventh distance L7 to the eighth distance L8, L7/L8.

FIG. 7E shows a specific example of the first crack 115T1 according to Embodiment 2. In the specific example in FIG. 7E, on the first section 131, the first crack 115T1 is exposed to or in contact with the side surface 651js. However, on the first section 131, the first crack 115T1 does not have to be exposed to or in contact with the side surface 651js. The first crack 115T1 according to Embodiment 2 may have the characteristics described in Embodiment 1. Also, FIG. 7C shows the angle θ2 according to Embodiment 2.

In the present embodiment, the composition of a material contained in the photoelectric conversion layer 51i is different from that of a material contained in the upper layer 651j. The molecular binding energy of a material contained in the upper layer 651j may be smaller than that of a material contained in the photoelectric conversion layer 51i.

In the present embodiment, the upper layer 651j is a carrier blocking layer. Specifically, the upper layer 651j is a hole blocking layer (HBL).

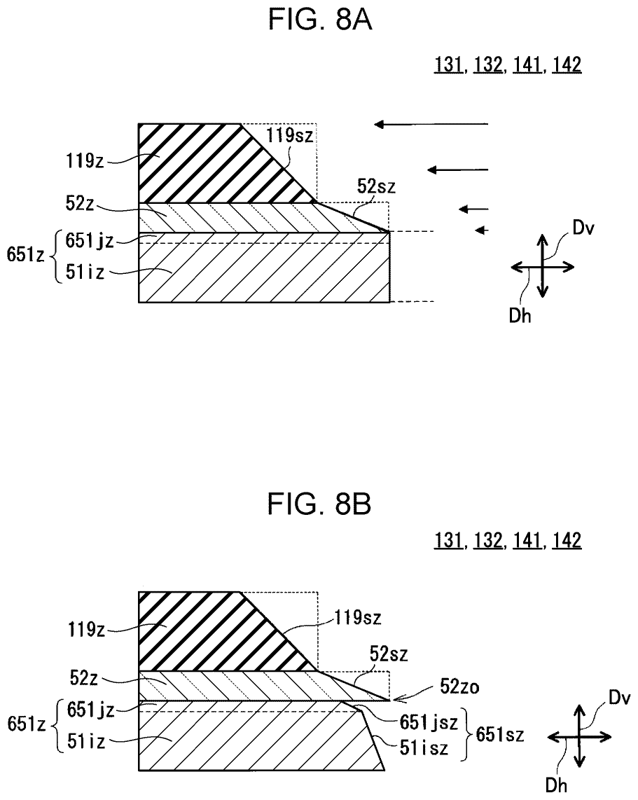

FIGS. 8A and 8B are diagrams illustrating dry etching of the photoelectric conversion film 651 in Embodiment 2. A method for manufacturing the image sensor 601 according to Embodiment 2 is described below with reference to FIGS. 8A and 8B.

As shown in FIG. 8A, a photoelectric conversion film 651z has a multilayer structure including the photoelectric conversion layer 51iz and an upper layer 651jz in this order from down to up. The upper layer 651jz is later processed into the upper layer 651j. The side surface of the photoelectric conversion film 651z and the side surface of the upper layer 651jz are hereinafter referred to as a side surface 651sz and a side surface 651jsz, respectively. The side surface 651sz includes the side surface 51isz and the side surface 651jsz.

The molecular binding energy of a material contained in the upper layer 651jz may be smaller than that of a material contained in the photoelectric conversion layer 51iz. In this case, in the dry etching using the third etching gas, the etching rate for the upper layer 651jz may be higher than the etching rate for the photoelectric conversion layer 51iz. For this reason, the side surface 651jsz may be retracted greatly to extend in a direction closer to the lateral direction Dh than the side surface 51isz.

In one specific example, the photoelectric conversion layer 51iz and the upper layer 651jz each contain an organic material. The molecular binding energy of the organic material contained in the upper layer 651jz may be smaller than that of the organic material contained in the photoelectric conversion layer 51iz. According to this specific example, the photoelectric conversion film 651 having the shape described with reference to FIGS. 7A and 7B may be obtained.

The photoelectric conversion film 651z the side portion of which has been ground by the dry etching using the third etching gas may be the photoelectric conversion film 651. The photoelectric conversion layer 51iz, the upper layer 651jz, the side surface 51isz, and the side surface 651jsz of the photoelectric conversion film 651z may be the photoelectric conversion layer 51i, the upper layer 651j, the side surface 51is, and the side surface 651js of the photoelectric conversion film 651, respectively.

As is understood from the above descriptions, the following descriptions can be applied to the method for manufacturing the image sensor 601 according to Embodiment 2. The photoelectric conversion film 651z includes the photoelectric conversion layer 51iz and the upper layer 651jz. The upper layer 651jz is located upward of the photoelectric conversion layer 51iz. In the dry etching using the third etching gas, the etching rate for the upper layer 651jz is higher than the etch rate for the photoelectric conversion layer 51iz. According to this manufacturing method, the photoelectric conversion film 651 including the photoelectric conversion layer 51i and the upper layer 651j can be manufactured. In the present embodiment, the molecular binding energy of a material contained in the upper layer 651jz may be smaller than that of a material contained in the photoelectric conversion layer 51iz.

### Embodiment 3

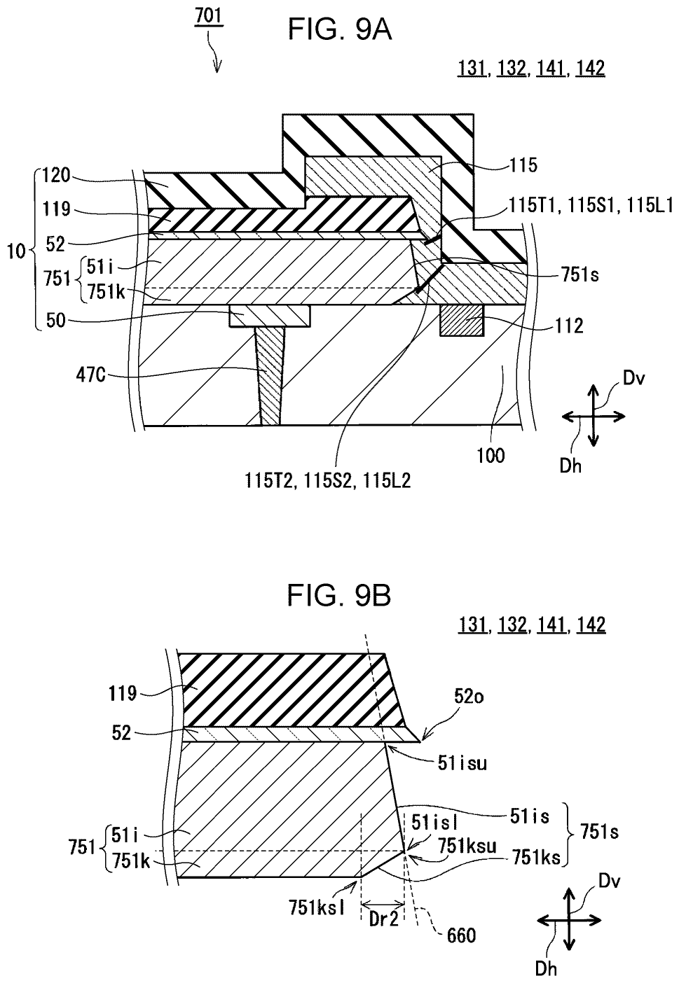

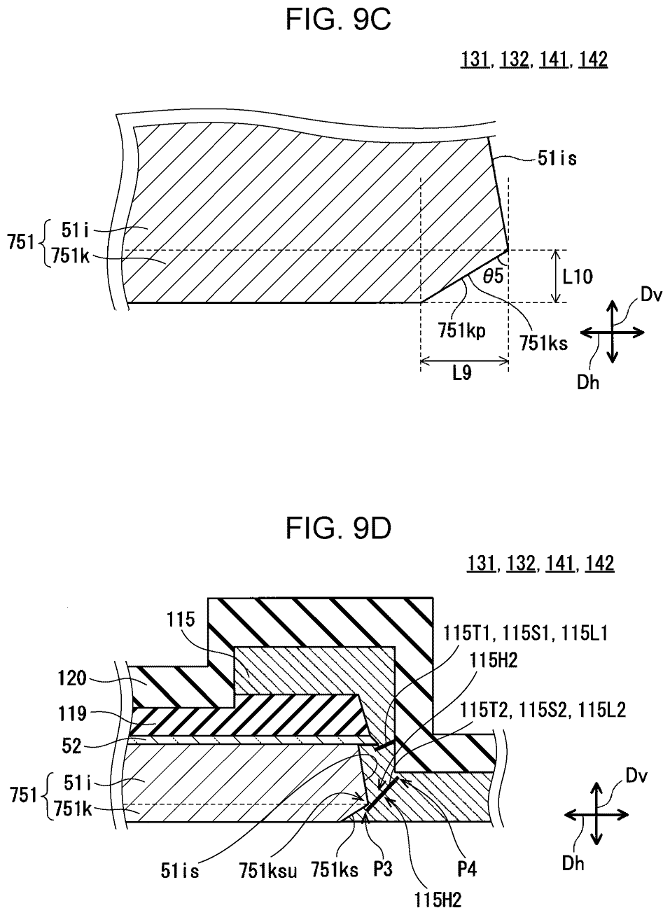

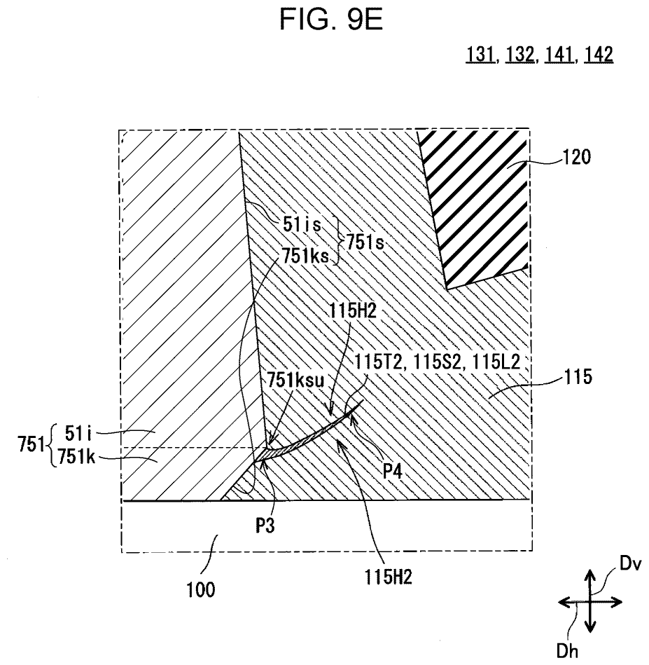

FIGS. 9A to 9E are partial sectional views of an image sensor 701 according to Embodiment 3. In the image sensor 701, a photoelectric conversion film 751 includes the photoelectric conversion layer 51i and a lower layer 751k. The lower layer 751k is located downward of the photoelectric conversion layer 51i. The side surface of the photoelectric conversion film 751 and the side surface of the lower layer 751k are hereinafter referred to as a side surface 751s and a side surface 751ks, respectively. The side surface 751s includes the side surface 51is and the side surface 751ks.

As shown in FIG. 9B, on the first section 131, the side surface 751ks of the lower layer 751k is located inward of the reference straight line 660. Thus, the side surface 751ks may be more inward than the side surface 51is. Thus, it is easier for the photoelectric conversion film 751 to have a round edge, which facilitates reduction of concentration of an electric field.

As shown in FIG. 9B, on the first section 131, a lower edge 751ksl of the side surface 751ks of the lower layer 751k is located inward of an upper edge 751ksu of the same. The distance between the lower edge 751ksl and the upper edge 751ksu in terms of the lateral direction Dh is defined as a second retraction distance Dr2. The second retraction distance Dr2 is, for example, greater than or equal to 30 nm and smaller than or equal to 70 nm and may be greater than or equal to 40 nm and smaller than or equal to 60 nm.

As shown in FIG. 9C, on the first section 131, the side surface 751ks of the lower layer 751k includes a fifth tapered portion 751kp spreading outward from down to up. An angle θ5 of the fifth tapered portion 751kp relative to the perpendicular direction Dv is greater than 0° and smaller than 90°. The angle θ5 is, for example, greater than or equal to 250 and smaller than or equal to 65° and may be greater than or equal to 350 and smaller than or equal to 60°.

The angle θ5 is described. The distance between the upper edge and the lower edge of the fifth tapered portion 751kp in terms of the lateral direction Dh is defined as a ninth distance L9. The distance between the upper edge and the lower edge of the fifth tapered portion 751kp in terms of the perpendicular direction Dv is defined as a tenth distance L10. The angle θ5 is the arctangent of the ratio of the ninth distance L9 to the tenth distance L10, L9/L10.

In the present embodiment, the composition of a material contained in the photoelectric conversion layer 51i is different from that of a material contained in the lower layer 751k. The molecular binding energy of a material contained in the lower layer 751k may be smaller than that of a material contained in the photoelectric conversion layer 51i.

In the present embodiment, the lower layer 751k is a carrier blocking layer. Specifically, the lower layer 751k is an electron blocking layer (EBL).

As shown in FIG. 9D, on the first section 131, a second crack 115T2 extends. On the first section 131, the second crack 115T2 includes a third portion P3 and a fourth portion P4. On the first section 131, the third portion P3 is located inward and downward of the upper edge 751ksu of the side surface 751ks of the lower layer 751k. On the first section 131, the fourth portion P4 is located outward and upward of the upper edge 751ksu. On the first section 131, the fourth portion P4 is located inside the connector 115. The second crack 115T2 of this configuration may mitigate stress in the connector 115. In the example in FIG. 9D, on the first section 131, the third portion P3 is located outward of the lower edge 751ksl of the side surface 751ks of the lower layer 751k. On the first section 131, the third portion P3 may be located inside the connector 115.

FIG. 9E shows a specific example of the second crack 115T2 according to Embodiment 3. In this specific example, on the first section 131, the second crack 115T2 is exposed to or in contact with the side surface 751ks. However, on the first section 131, the second crack 115T2 does not have to be exposed to or in contact with the side surface 751ks.

In the specific example in FIG. 9E, on the first section 131, the second crack 115T2 is disconnected midway in the connector 115. However, on the first section 131, the second crack 115T2 may run across the connector 115. Similarly, on the first section 131, the first crack 115T1 may be disconnected midway in the connector 115 or may run across the connector 115.

Also, in the specific example in FIG. 9E, on the first section 131, the second crack 115T2 is bent upward as it goes outward. However, on the first section 131, the second crack 115T2 may be straight. Similarly, on the first section 131, the first crack 115T1 may be straight or may be bent upward as it goes outward.

The second crack 115T2 may include at least one of a second gap 115S2 or a second low density portion 115L2. On the first section 131, the connector 115 may be exposed in the second gap 115S2. On the first section 131, the second low density portion 115L2 may be adjacently sandwiched between two second high density portions 115H2. On the first section 131, the second low density portion 115L2 may be a seam between the two second high density portions 115H2. The density of the second low density portion 115L2 is lower than that of the two second high density portions 115H2. The second low density portion 115L2 and the two second high density portions 115H2 are portions included in the connector 115.

On the first section 131, the second crack 115T2 may extend continuously. On the first section 131, the second crack 115T2 may extend upward as it goes outward. On the first section 131, the second crack 115T2 may have a relatively thick portion and a relatively thin portion. For example, on the first section 131, the second gap 115S2 may have a portion thicker than the second low density portion 115L2. Also, for example, on the first section 131, the third portion P3 may be thicker than the fourth portion P4. On the first section 131, the second crack 115T2 may or may not be exposed to or in contact with the side surface 751ks of the lower layer 751k.

In a third specific example, on the first section 131, the second gap 115S2 includes the third portion P3, and the second low density portion 115L2 includes the fourth portion P4. On the first section 131, the side surface 751ks of the lower layer 751k is exposed in the second gap 115S2. On the first section 131, one of the two second high density portions 115H2 is in contact with the side surface 51is of the photoelectric conversion layer 51i.

In a fourth specific example, on the first section 131, the second low density portion 115L2 includes the third portion P3 and the fourth portion P4. On the first section 131, the second low density portion 115L2 is in contact with the side surface 751ks of the lower layer 751k. On the first section 131, one of the two second high density portions 115H2 is in contact with the side surface 51is of the photoelectric conversion layer 51i.

In the image sensor according to this example, as seen three-dimensionally, the second crack 115T2 extends in the shape of a strip. In a plan view, the second crack 115T2 extends along the side surface 51s of the photoelectric conversion film 51.

In the example in FIG. 9D, the following descriptions can also be applied to the connector 115. On the first section 131, the connector 115 includes a third connection portion, a fourth connection portion, and a strip-shaped second seam connecting the upper surface of the third connection portion and the lower surface of the fourth connection portion. On the first section 131, the upper surface of the third connection portion includes a portion located inward and downward of the upper edge 751ksu of the side surface 751ks of the lower layer 751k and a portion located outward and upward of the upper edge 751ksu. On the first section 131, the upper surface of the third connection portion may extend upward as it goes outward. The third connection portion may correspond to one of the two second high density portions 115H2. The fourth connection portion may correspond to the other one of the two second high density portions 115H2. The second seam may correspond to the second low density portion 115L2.

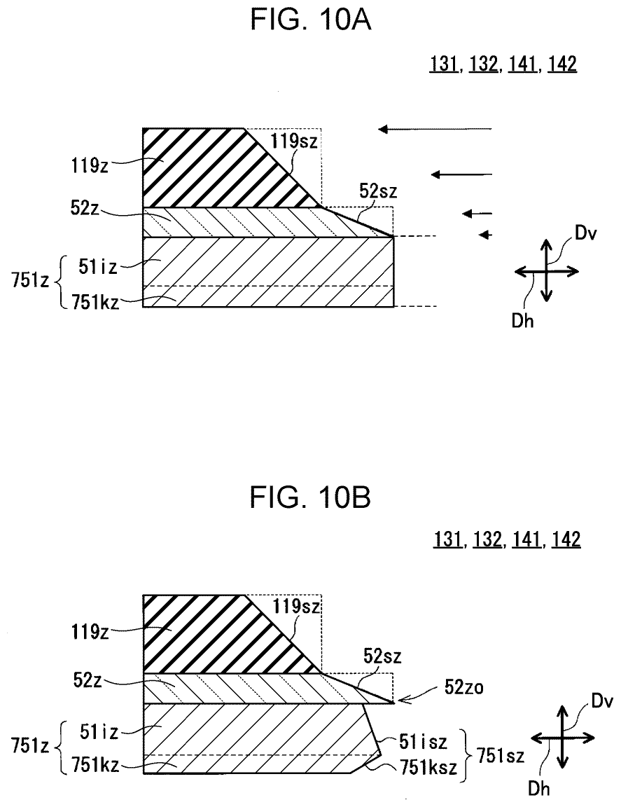

FIGS. 10A and 10B are diagrams illustrating dry etching of the photoelectric conversion film 751 in Embodiment 3. A method for manufacturing the image sensor 701 according to Embodiment 3 is described below with reference to FIGS. 10A and 10B.

As shown in FIG. 10A, a photoelectric conversion film 751z has a multilayer structure including a lower layer 751kz and the photoelectric conversion layer 51iz in this order from down to up. The lower layer 751kz is later processed into the lower layer 751k. The side surface of the photoelectric conversion film 751z and the side surface of the lower layer 751kz are hereinafter referred to as a side surface 751sz and a side surface 751ksz, respectively. The side surface 751sz includes the side surface 51isz and the side surface 751ksz.

The molecular binding energy of a material contained in the lower layer 751kz may be smaller than that of a material contained in the photoelectric conversion layer 51iz. In this case, in the dry etching using the third etching gas, the etching rate for the lower layer 751kz may be higher than the etching rate for the photoelectric conversion layer 51iz. For this reason, unlike the side surface 51isz, the side surface 751ksz may be retracted in such a manner as to spread outward from down to up.

In one specific example, the photoelectric conversion layer 51iz and the lower layer 751kz each contain an organic material. The molecular binding energy of the organic material contained in the lower layer 751kz may be smaller than that of the organic material contained in the photoelectric conversion layer 51iz. According to this specific example, the photoelectric conversion film 751 having the shape described with reference to FIGS. 9A and 9B may be obtained.

The photoelectric conversion film 751z the side portion of which has been ground by the dry etching using the third etching gas may be the photoelectric conversion film 751. The photoelectric conversion layer 51iz, the lower layer 751kz, the side surface 51isz, and the side surface 751ksz of the photoelectric conversion film 751z may be the photoelectric conversion layer 51i, the lower layer 751k, the side surface 51is, and the side surface 751ks of the photoelectric conversion film 751, respectively.

In Embodiment 3, the dry etching using the third etching gas yields a state where the upper edge 751ksu of the side surface 751ks of the lower layer 751k is located outward of the lower edge 751ksl of the same. The second crack 115T2 can be formed by execution of the “(F) Step of Disposing the Connectors” in this state. Specifically, because the upper edge 751ksu is located outward of the lower edge 751ksl, the continuity of the film formed by deposition of the connector 115z from up to down may be disconnected. The second crack 115T2 may be formed due to this disconnection.

As is understood from the above descriptions, the following descriptions can be applied to the method for manufacturing the image sensor 701 according to Embodiment 3. The photoelectric conversion film 751z includes the photoelectric conversion layer 51iz and the lower layer 751kz. The lower layer 751kz is located downward of the photoelectric conversion layer 51iz. In the dry etching using the third etching gas, the etching rate for the lower layer 751kz is higher than the etching rate for the photoelectric conversion layer 51iz. According to this manufacturing method, the photoelectric conversion film 751 including the photoelectric conversion layer 51i and the lower layer 751k can be manufactured. In the present embodiment, the molecular binding energy of a material contained in the lower layer 751kz may be smaller than that of a material contained in the photoelectric conversion layer 51iz.

### Embodiment 4

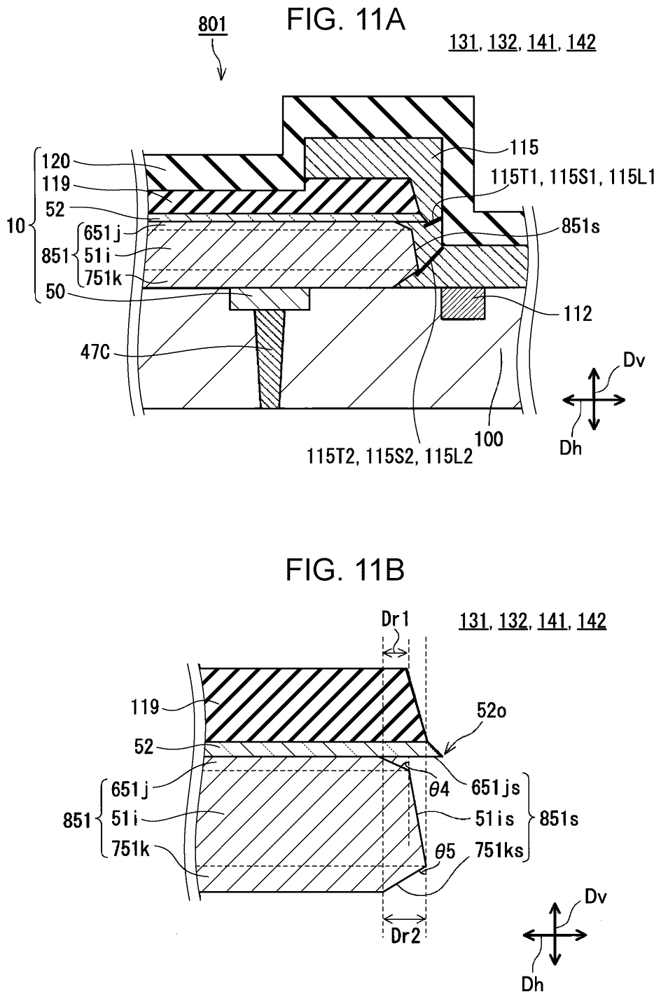

FIGS. 11A and 11B are partial sectional views of an image sensor 801 according to Embodiment 4. In the image sensor 801, a photoelectric conversion film 851 includes the photoelectric conversion layer 51i, the upper layer 651j, and the lower layer 751k. The side surface of the photoelectric conversion film 851 is hereinafter referred to as a side surface 851s. The side surface 851s includes the side surfaces 51is, 651js and the side surface 751ks.

In an example in FIG. 11B, the second retraction distance Dr2 is larger than the first retraction distance Dr1. However, the second retraction distance Dr2 may be the same as the first retraction distance Dr1 or may be smaller than the first retraction distance Dr1. The angle θ5 may be larger than, smaller than, or the same as the angle θ4.

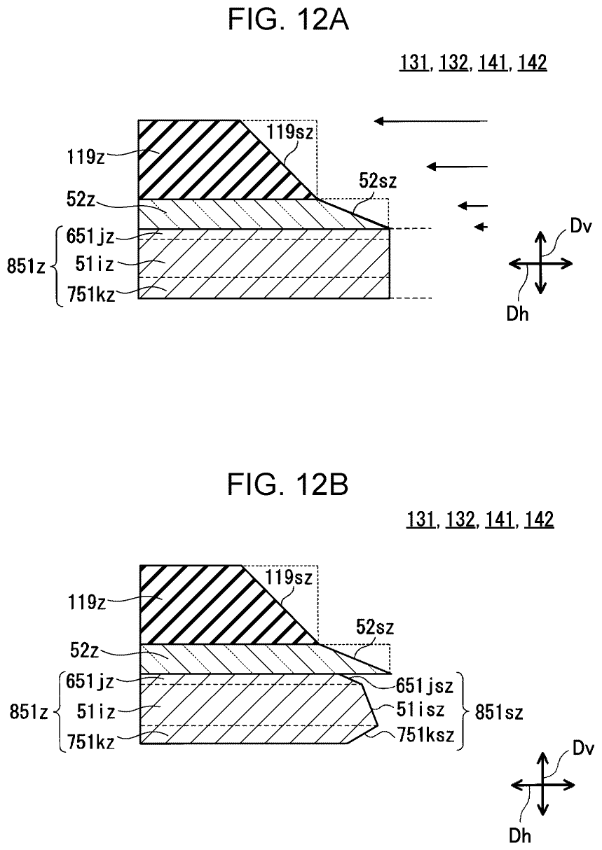

FIGS. 12A and 12B are diagrams illustrating dry etching of the photoelectric conversion film 851 in Embodiment 4. A photoelectric conversion film 851z has a multilayer structure including the lower layer 751kz, the photoelectric conversion layer 51iz, and the upper layer 651jz in this order from down to up. The side surface of the photoelectric conversion film 851z is hereinafter referred to as a side surface 851sz. The side surface 851sz includes the side surface 51isz, the side surface 651jsz, and the side surface 751ksz.

In one specific example, the photoelectric conversion layer 51iz, the upper layer 651jz, and the lower layer 751kz of the photoelectric conversion film 851z each contain an organic material. The molecular binding energy of the organic material contained in the upper layer 651jz is smaller than that of the organic material contained in the photoelectric conversion layer 51iz. The molecular binding energy of the organic material contained in the lower layer 751kz is smaller than that of the organic material contained in the photoelectric conversion layer 51iz. According to this specific example, the photoelectric conversion film 851 having the shape described with reference to FIGS. 11A and 11B may be obtained.

### OTHER EMBODIMENTS

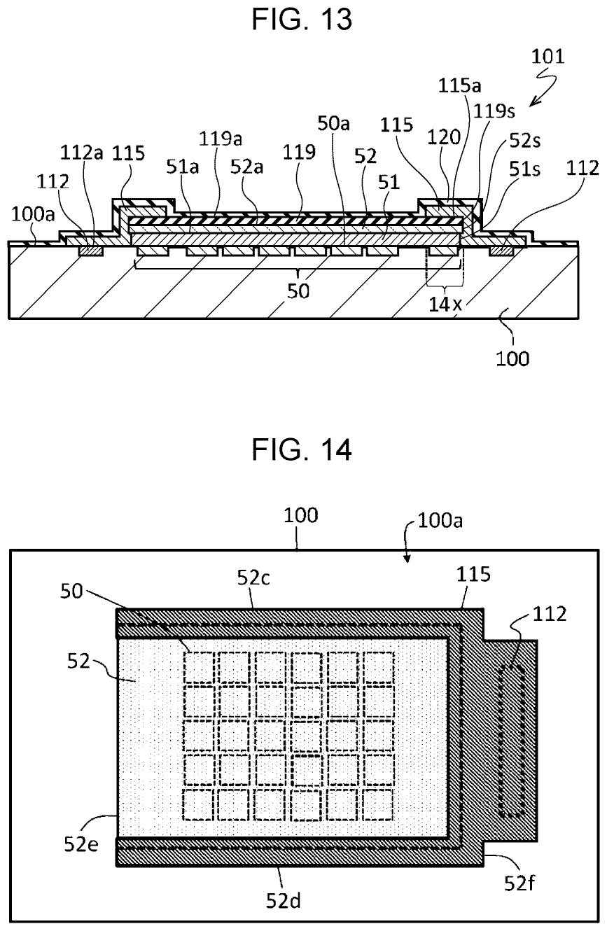

FIGS. 13 to 17 are sectional views or top views showing an image sensor according to other embodiments.

In the example in FIG. 13, the connectors 115 each have a portion 115a covering the upper surface 119a of the insulating film 119 and overlapping with at least one of the lower electrodes 50 in a plan view. For a pixel 14x to which the lower electrode 50 overlapping with the portion 115a in a plan view belongs, the connector 115 functions as a light blocking film. Thus, the pixel 14x can be used to obtain optical black.

In the example in FIG. 14, the side surface 52s extends from the sides 52c, 52d, and the 52f, and the connector 115 is in contact with the side surface 52s. This configuration is advantageous from the perspective of increasing the area of contact between the connector 115 and the upper electrode 52 and reducing the electric resistance between them.

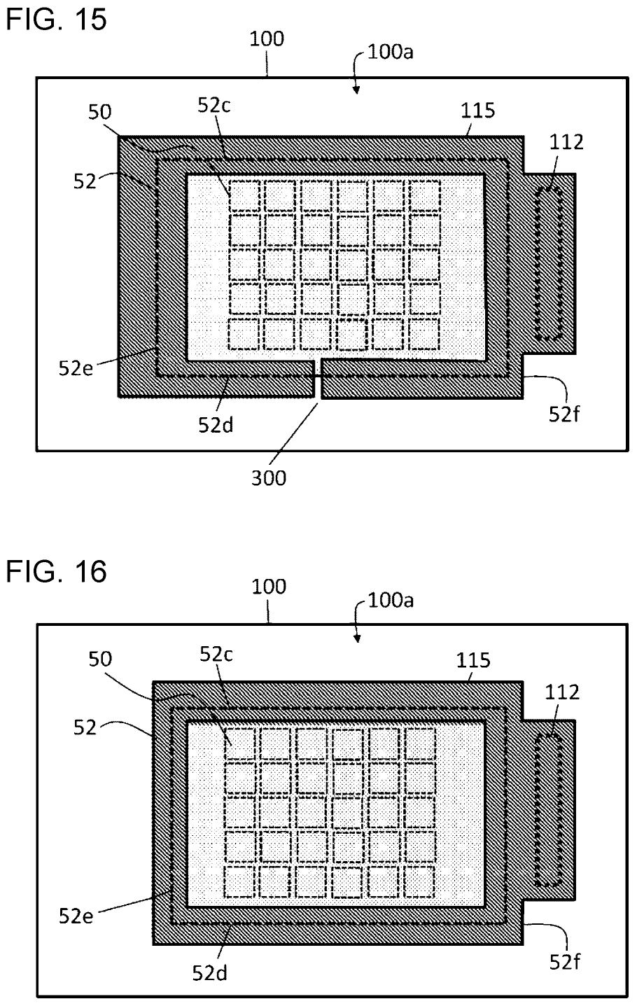

In the examples in FIGS. 15 and 16, the side surface 52s extends from the sides 52c, 52d, 52e, and 52f of the lower surface 52b of the upper electrode 52, and the connector 115 is in contact with this side surface 52s. In a plan view, the connector 115 has a frame shape, surrounding a predetermined region. As shown in FIG. 15, the frame shape of the connector 115 may be a frame shape unclosed by an interstice 300. As shown in FIG. 16, the frame shape of the connector 115 may be closed.

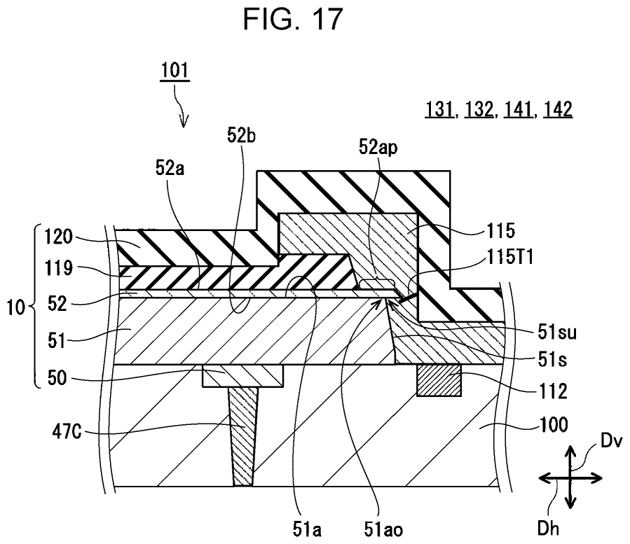

In the example in FIG. 17, part of the upper surface 52a, specifically an outer periphery portion 52ap of the upper surface 52a, is not covered by the insulating film 119. The outer periphery portion 52ap is covered by the connector 115 and is in contact with the connector 115. This configuration is advantageous from the perspective of increasing the area of contact between the connector 115 and the upper electrode 52 and reducing the electric resistance between them.

The image sensor of the present disclosure may be used in imaging devices for various uses.

What is claimed is:

1. An image sensor comprising:
a photoelectric conversion film;
an upper electrode located on or above the photoelectric conversion film; and
a connector electrically connected to the upper electrode, wherein
on a first section parallel to a direction perpendicular to the photoelectric conversion film,
the connector is in contact with a side surface of the photoelectric conversion film, and
the upper electrode extends to a position outward of an outer edge of an upper surface of the photoelectric conversion film.

2. The image sensor according to claim 1, wherein
the upper surface of the photoelectric conversion film includes a contact surface between the photoelectric conversion film and the upper electrode, and
on the first section, at a same position as the contact surface in the direction perpendicular to the photoelectric conversion film, a side surface of the upper electrode is located outward of the side surface of the photoelectric conversion film.

3. The image sensor according to claim 1, wherein
on the first section, a side surface of the upper electrode includes a first tapered portion spreading outward from an upper surface of the upper electrode toward a lower surface of the upper electrode.

4. The image sensor according to claim 1, wherein
on the first section, an upper edge of the side surface of the photoelectric conversion film is located more inward in the photoelectric conversion film than a lower edge of the side surface of the photoelectric conversion film.

5. The image sensor according to claim 1, further comprising a first crack including a first portion and a second portion, wherein
on the first section,
the first portion is located inward and downward of an outer edge of the upper electrode,
the second portion is located outward and upward of the outer edge of the upper electrode, and
the second portion is located inside the connector.

6. The image sensor according to claim 1, wherein
the photoelectric conversion film includes a photoelectric conversion layer and an upper layer,
the upper layer is located on or above the photoelectric conversion layer, and
on the first section, a side surface of the upper layer is located inward of a straight line including an upper edge of a side surface of the photoelectric conversion layer and a lower edge of the side surface of the photoelectric conversion layer.

7. The image sensor according to claim 1, wherein
the photoelectric conversion film includes a photoelectric conversion layer and a lower layer,
the lower layer is located on or below the photoelectric conversion layer, and
on the first section, a side surface of the lower layer is located inward of a straight line including an upper edge of a side surface of the photoelectric conversion layer and a lower edge of the side surface of the photoelectric conversion layer.

8. The image sensor according to claim 7, wherein
a lower edge of the side surface of the lower layer is located inward of an upper edge of the side surface of the lower layer.

9. The image sensor according to claim 8, further comprising a second crack including a third portion and a fourth portion, wherein
on the first section,
the third portion is located inward and downward of the upper edge of the side surface of the lower layer,
the fourth portion is located outward and upward of the upper edge of the side surface of the lower layer, and
the fourth portion is located inside the connector.

10. The image sensor according to claim 1, wherein
on the first section, the side surface of the photoelectric conversion film includes a second tapered portion spreading outward from the upper surface of the photoelectric conversion film toward a lower surface of the photoelectric conversion film.

11. The image sensor according to claim 1, further comprising an insulating film, wherein
on the first section,
the connector, the insulating film, and the upper electrode are disposed in this order from an upper side to a lower side of the image sensor, and
an upper surface of the upper electrode is spaced away from the connector.

12. The image sensor according to claim 1, further comprising an insulating film, wherein
on the first section, a side surface of the insulating film is continuous with a side surface of the upper electrode.

13. The image sensor according to claim 1, wherein
on a second section of the image sensor parallel to the direction perpendicular to the photoelectric conversion film and orthogonal to the first section, the upper electrode extends to a position outward of the outer edge of the upper surface of the photoelectric conversion film.

14. The image sensor according to claim 1, wherein
a material of the upper electrode has a light transmittance higher than a light transmittance of a material of the connector.

15. The image sensor according to claim 1, wherein
the connector has a light blocking property.

16. An imaging device comprising:
the image sensor according to claim 1; and
a peripheral circuit that controls the image sensor.

17. A method for manufacturing an image sensor, the method comprising:
obtaining a structure including a photoelectric conversion film and an upper electrode located on or above the photoelectric conversion film;
by using an etching gas that etches the photoelectric conversion film at an etching rate higher than an etching rate for the upper electrode, performing dry etching to etch a side surface of the photoelectric conversion film while forming a space that is located inward and downward of an outer edge of the upper electrode; and
after the dry etching, disposing a connector that is electrically connected to the upper electrode and that is in contact with the side surface of the photoelectric conversion film,
wherein the side surface of the photoelectric conversion film is exposed in the space in the dry etching.

18. The method for manufacturing an image sensor according to claim 17, wherein
the photoelectric conversion film includes a photoelectric conversion layer and an upper layer,
the upper layer is located on or above the photoelectric conversion layer, and
in the dry etching, an etching rate for the upper layer is higher than an etching rate for the photoelectric conversion layer.

19. The method for manufacturing an image sensor according to claim 17, wherein
the photoelectric conversion film includes a photoelectric conversion layer and a lower layer,
the lower layer is located on or below the photoelectric conversion layer, and
in the dry etching, an etching rate for the lower layer is higher than an etching rate for the photoelectric conversion layer.

20. The method for manufacturing an image sensor according to claim 17, wherein
in the dry etching, a flow of the etching gas is formed, from a location upward of the upper electrode to a location downward of the upper electrode.
